(19) United States
(12) Patent Application Publication
(10) Pub. No.: US 2026/0082575 A1
(43) Pub. Date: Mar. 19, 2026

(54) SEMICONDUCTOR STORAGE DEVICE

(71) Applicant: Kioxia Corporation, Tokyo (JP)

(72) Inventor: Hiroyuki KUTSUKAKE, Kuwana Mie (JP)

(73) Assignee: Kioxia Corporation, Tokyo (JP)

(21) Appl. No.: 19/079,650

(22) Filed: Mar. 14, 2025

(30) Foreign Application Priority Data
Sep. 19, 2024 (JP) 2024-162568

(51) Int. Cl. H10B 43/40; G11C 16/08; H10B 41/27; H10B 41/41; H10B 43/27

(52) U.S. Cl. CPC H10B 43/40; G11C 16/08; H10B 41/27; H10B 41/41; H10B 43/27

(57) ABSTRACT

A semiconductor storage device according to the present disclosure includes a semiconductor substrate including a first region which is a source region or a drain region and a second region which is spaced from the first region in a first direction and which is the source region or the drain region, a first contact connected to the first region, a second contact connected to the second region, a first memory cell connected to the first contact, a gate electrode formed between the first contact and the second contact, a first conductor having a height equal to a height of the gate electrode and electrically connected to the first contact, and a second conductor having a height equal to the height of the gate electrode, having at least a portion formed between the gate electrode and the second contact, and insulated from the gate electrode, the first contact, and the second contact.

### CROSS-REFERENCE TO RELATED APPLICATION

This application is based upon and claims the benefit of priority from the prior Japanese Patent Applications No. 2024-162568, filed on Sep. 19, 2024, the entire contents of which are incorporated herein by reference.

### FIELD

The present embodiment relates to a semiconductor storage device.

### BACKGROUND

NAND flash memories are known as semiconductor storage devices that can store data in a nonvolatile manner. A semiconductor storage device such as a NAND flash memory employs a three-dimensional memory structure for higher integration and higher capacity.

### BRIEF DESCRIPTION OF THE DRAWINGS

FIG. 1 is a block diagram showing an example of a configuration of a memory system including a semiconductor storage device according to an embodiment;

FIG. 2 is a circuit diagram showing an example of a circuit configuration of a memory cell array included in the semiconductor storage device according to the embodiment;

FIG. 3 is a cross-sectional view showing an example of a cross-sectional structure of the semiconductor storage device according to the embodiment;

FIG. 4 is a circuit diagram showing an example of a configuration of a row decoder module, a driver module, and the memory cell array of the semiconductor storage device according to the embodiment;

FIG. 5 is a circuit diagram showing an example of a configuration of a block decoder included in the semiconductor storage device according to the embodiment;

FIG. 6 is a plan view showing an example of a planar structure of the row decoder module of the semiconductor storage device according to the embodiment;

FIG. 7 is a plan view showing an example of a planar structure of transfer transistors included in the semiconductor storage device according to the embodiment;

FIG. 8A is a cross-sectional view taken along the line A-A in FIG. 7, showing an example of a cross-sectional structure of the transfer transistors included in the semiconductor storage device according to the embodiment;

FIG. 8B is a cross-sectional view taken along the line B-B in FIG. 7, showing an example of a cross-sectional structure of the transfer transistors included in the semiconductor storage device according to the embodiment;

FIG. 9A is a cross-sectional view showing a configuration of a transfer transistor according to a comparative example;

FIG. 9B is a cross-sectional view showing a configuration of a transfer transistor according to the embodiment;

FIG. 10 is a plan view showing an example of a planar structure of transfer transistors included in a semiconductor storage device according to an embodiment;

FIG. 11 is a plan view showing an example of a planar structure of transfer transistors included in a semiconductor storage device according to an embodiment;

FIG. 12 is a plan view showing an example of a planar structure of transfer transistors included in a semiconductor storage device according to an embodiment;

FIG. 13 is a plan view showing an example of a planar structure of transfer transistors included in a semiconductor storage device according to an embodiment;

FIG. 14 is a plan view showing an example of a planar structure of transfer transistors included in a semiconductor storage device according to an embodiment;

FIG. 15 is a plan view showing an example of a planar structure of a plurality of transfer transistors included in a semiconductor storage device according to an embodiment;

FIG. 16A is a schematic view showing a process of manufacturing transfer transistors included in the semiconductor storage device according to the embodiment;

FIG. 16B is a schematic view showing the process of manufacturing the transfer transistors included in the semiconductor storage device according to the embodiment;

FIG. 16C is a schematic view showing the process of manufacturing the transfer transistors included in the semiconductor storage device according to the embodiment;

FIG. 16D is a schematic view showing the process of manufacturing the transfer transistors included in the semiconductor storage device according to the embodiment;

FIG. 16E is a schematic view showing the process of manufacturing the transfer transistors included in the semiconductor storage device according to the embodiment;

FIG. 16F is a schematic view showing the process of manufacturing the transfer transistors included in the semiconductor storage device according to the embodiment;

FIG. 16G is a schematic view showing the process of manufacturing the transfer transistors included in the semiconductor storage device according to the embodiment;

FIG. 16H is a schematic view showing the process of manufacturing the transfer transistors included in the semiconductor storage device according to the embodiment;

FIG. 16I is a schematic view showing the process of manufacturing the transfer transistors included in the semiconductor storage device according to the embodiment;

FIG. 16J is a schematic view showing the process of manufacturing the transfer transistors included in the semiconductor storage device according to the embodiment;

FIG. 16K is a schematic view showing the process of manufacturing the transfer transistors included in the semiconductor storage device according to the embodiment; and

FIG. 16L is a schematic view showing the process of manufacturing the transfer transistors included in the semiconductor storage device according to the embodiment.

### DETAILED DESCRIPTION

In general, according to the embodiment, a semiconductor storage device includes a semiconductor substrate including a first region which is a source region or a drain region and a second region which is spaced from the first region in a first direction and which is the source region or the drain region, a first contact connected to the first region, a second contact connected to the second region, a first memory cell connected to the first contact, a gate electrode formed between the first contact and the second contact, a first conductor including a portion having a height equal to a height of the gate electrode and electrically connected to the first contact, and a second conductor including a portion having a height equal to the height of the gate electrode, having at least a portion formed between the gate electrode and the second contact, and insulated from the gate electrode, the first contact, and the second contact.

Note that a “semiconductor substrate including a ‘first region’ and a ‘second region’” includes a known configuration such as a configuration in which a source region or a drain region which is the first region or the second region is formed in a P-type well region or an N-type well region provided in a semiconductor layer laminated on a substrate such as a silicon substrate constituting a semiconductor wafer.

### 1 First Embodiment

### 1. Embodiment

### 1.1 Configuration

### 1.1.1 Memory System

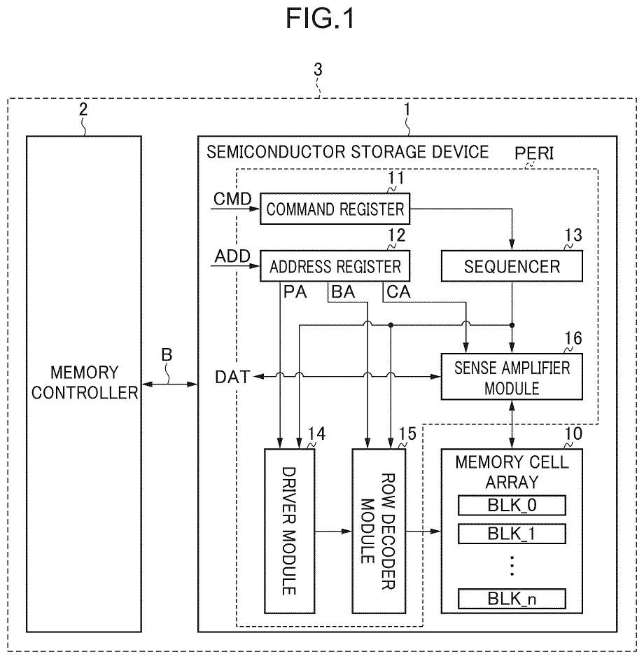

FIG. 1 is a block diagram showing an example of a configuration of a memory system including the semiconductor storage device according to the embodiment.

A memory system 3 includes a semiconductor storage device 1 and a memory controller 2.

Examples of the memory system 3 include a memory card such as a SD card, a Universal Flash Storage (UFS), and a Solid State Drive (SSD). The memory system 3 is connected to an external host apparatus not illustrated.

The memory controller 2 is formed of an integration circuit such as a System-on-a-Chip (SoC), for example. The memory controller 2 controls the semiconductor storage device 1 based on a request from the host apparatus. Specifically, for example, the memory controller 2 writes data, writing of which has been requested from the host apparatus, into the semiconductor storage device 1. The memory controller 2 reads out data, readout of which has been requested from the host apparatus, from the semiconductor storage device 1 and transmits the data to the host apparatus.

The semiconductor storage device 1 is a NAND flash memory, for example. The semiconductor storage device 1 stores data in a nonvolatile manner. The semiconductor storage device 1 is connected to the memory controller 2 via a NAND bus B.

The NAND bus B is a bus in conformity with a single data rate (SDR) interface, a toggle double data rate (DDR) interface, or an open NAND flash interface (ONFI), for example.

### 1.1.2 Semiconductor Storage Device

An internal configuration of the semiconductor storage device 1 according to the embodiment will be described still with reference to the block diagram shown in FIG. 1. The semiconductor storage device 1 includes a memory cell array 10 and a peripheral circuit PERI, for example. The peripheral circuit PERI includes a command register 11, an address register 12, a sequencer 13, a driver module 14, a row decoder module 15, and a sense amplifier module 16.

The memory cell array 10 includes a plurality of blocks BLK0 to BLKn (n being an integer more than or equal to one). The block BLK is a set of a plurality of memory cell transistors that can store data in a nonvolatile manner and is used as a data erasure unit, for example. The memory cell array 10 is provided with a plurality of bit lines and a plurality of word lines. One memory cell transistor is associated with one bit line and one word line, for example.

The command register 11 holds a command CMD received by the semiconductor storage device 1 from the memory controller 2. The command CMD includes instructions for causing the sequencer 13 to execute a readout operation, a write operation, an erase operation, and the like, for example.

The address register 12 holds address information ADD received by the semiconductor storage device 1 from the memory controller 2. The address information ADD includes a page address PA, a block address BA, and a column address CA, for example. The page address PA, the block address BA, and the column address CA, for example, are used for selection of a word line, a block BLK, and a bit line, respectively.

The sequencer 13 controls an overall operation of the semiconductor storage device 1. For example, the sequencer 13 controls the driver module 14, the row decoder module 15, the sense amplifier module 16, and the like based on the command CMD held in the command register 11, to execute the readout operation, the write operation, the erase operation, and the like.

The driver module 14 generates a voltage to be used for the readout operation, the write operation, the erase operation, and the like. The driver module 14 then supplies (applies) the generated voltage to a signal line corresponding to a selected word line based on the page address PA held in the address register 12, for example.

The row decoder module 15 selects one block BLK in the corresponding memory cell array 10 based on the block address BA held in the address register 12. The row decoder module 15 then transfers the voltage supplied to the signal line corresponding to the selected word line, for example, to a selected word line in the selected block BLK.

The sense amplifier module 16 transfers data DAT between the memory controller 2 and the memory cell array 10. The data DAT includes written data and read-out data. More specifically, in the write operation, the sense amplifier module 16 transfers written data received from the memory controller 2 to the memory cell array 10. In the readout operation, the sense amplifier module 16 executes a determination of data stored in memory cell transistors based on the voltage of a bit line. The sense amplifier module 16 then transfers a result of the determination as read-out data to the memory controller 2.

### 1.1.3 Circuit Configuration of Memory Cell Array

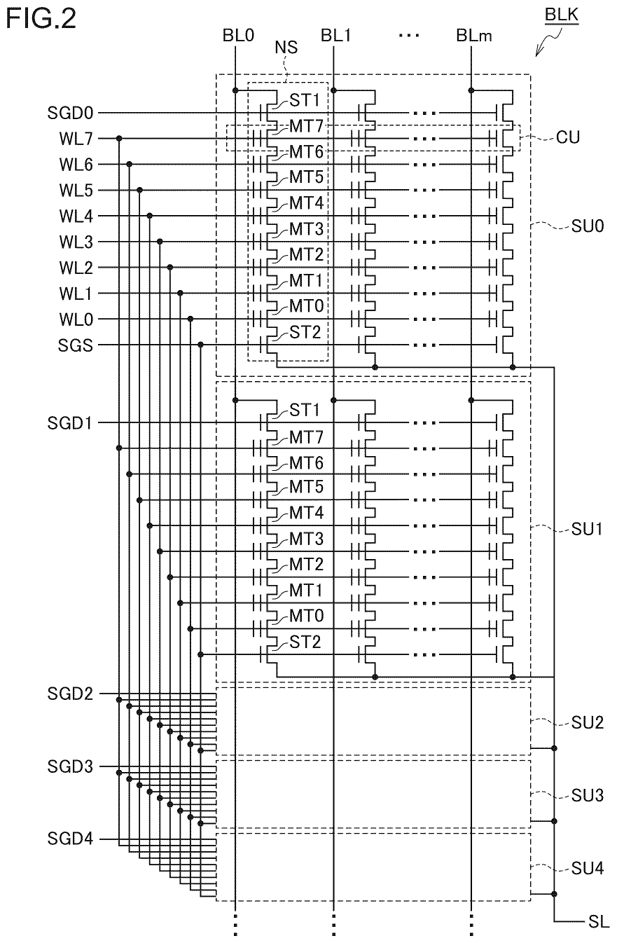

FIG. 2 is a circuit diagram showing an example of a circuit configuration of the memory cell array included in the semiconductor storage device according to the embodiment. FIG. 2 shows one block BLK among the plurality of blocks BLK included in the memory cell array 10. In the example shown in FIG. 2, the block BLK includes five string units SU0 to SU4, for example.

Each of the string units SU includes a plurality of NAND strings NS associated with bit lines BL0 to BLm (m being an integer more than or equal to one), respectively. Each of the NAND strings NS includes memory cell transistors MT0 to MT7 as well as select transistors ST1 and ST2, for example. Each of the memory cell transistors MT0 to MT7 includes a control gate and a charge accumulation layer, and holds data in a nonvolatile manner. Each of the select transistors ST1 and ST2 is used for selection of the string unit SU during various operations. Note that in the following description, each of the memory cell transistors MT0 to MT7 will also be called a memory cell transistor MT. Some of the memory cell transistors MT include a dummy cell transistor (not shown) which is not used for effective data holding in some cases.

In each of the NAND strings NS, the memory cell transistors MT0 to MT7 are connected in series. One end of the select transistor ST1 is connected to an associated bit line BL, and the other end of the select transistor ST1 is connected to one end of the memory cell transistors MT0 to MT7 connected in series. One end of the select transistor ST2 is connected to the other end of the memory cell transistors MT0 to MT7 connected in series. The other end of the select transistor ST2 is connected to the source line SL.

In the same block BLK, control gates of the memory cell transistors MT0 to MT7 are connected to word lines WL0 to WL7, respectively. Gates of the select transistors ST1 in the string units SU0 to SU4 are connected to select gate lines SGD0 to SGD4, respectively. In contrast, gates of a plurality of the select transistors ST2 are connected in common to a select gate line SGS. However, this is not a limitation, and the gates of the plurality of select transistors ST2 may be respectively connected to a plurality of select gate lines that are different for each of the string units SU. Note that in the following description, in a case in which the word lines WL0 to WL7 are not distinguished from one another, they will simply be called a word line WL. In a case in which the select gate lines SGD0 to SGD4 are not distinguished from one another, they will simply be called a select gate line SGD.

Each of the bit lines BL0 to BLm connects in common one NAND string NS included in each of the string units SU among the plurality of blocks BLK. Each of the word lines WL0 to WL7 is provided for each of the blocks BLK. The source line SL is shared by the plurality of blocks BLK, for example.

A set of the plurality of memory cell transistors MT connected to a common word line WL in one string unit SU will be called a cell unit CU, for example. For example, a storage capacity of the cell unit CU including the memory cell transistors MT each storing 1-bit data is defined as “one-page data”. The cell unit CU may have a storage capacity more than or equal to two-page data in accordance with the number of bits of data stored in the memory cell transistor MT.

Note that the circuit configuration of the memory cell array 10 included in the semiconductor storage device 1 according to the embodiment is not limited to the configuration described above. For example, the number of the string units SU included in each of the blocks BLK may be designed at any number. The number of the memory cell transistors MT as well as the number of the select transistors ST1 and ST2 included in each of the NAND strings NS may each be designed at any number.

### 1.1.4 Cross-Sectional Structure of Semiconductor Storage Device

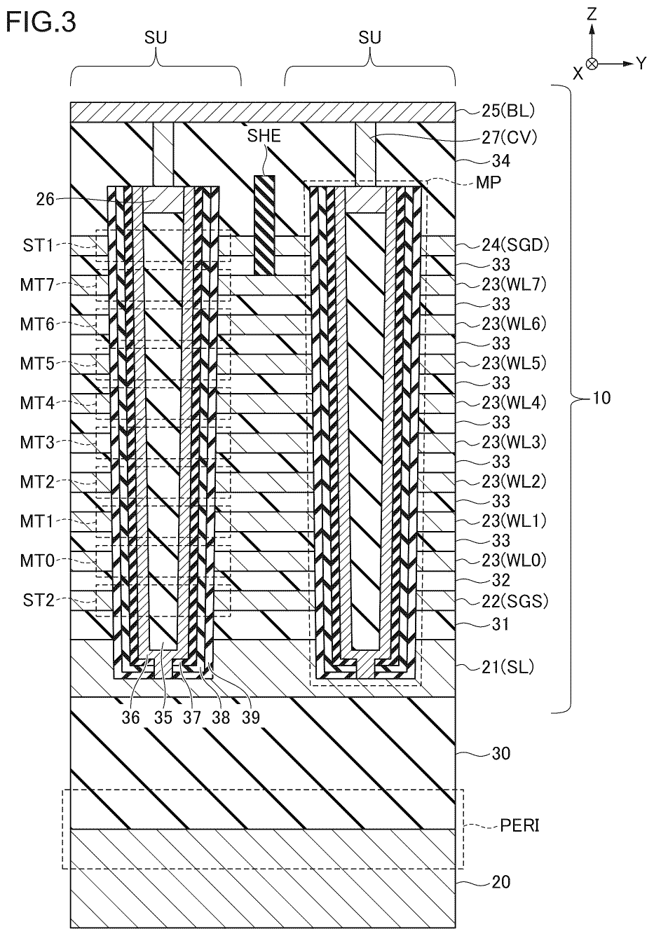

A cross-sectional structure of the semiconductor storage device 1 according to the embodiment will now be described using FIG. 3. FIG. 3 is a cross-sectional view showing an example of the cross-sectional structure of the semiconductor storage device according to the embodiment. FIG. 3 shows a cross-sectional structure including two string units SU among the five string units SU included in one block BLK.

Note that in the drawings as will be referred to below, the X-direction corresponds to a direction in which the word line WL extends, the Y-direction corresponds to a direction in which the bit line BL extends, and the Z-direction corresponds to a direction vertical to a surface of a semiconductor substrate 20 on which the semiconductor storage device 1 is formed.

The memory cell array 10 includes conductor layers 21, 22, 24, and 25 provided above the semiconductor substrate 20, a plurality of conductor layers 23, and a plurality of memory pillars MP (only two of which are shown in FIG. 3). Note that in the following description, a direction in which the memory cell array 10 is provided on the semiconductor substrate 20 shall be an upward direction. The opposite direction thereof shall be a downward direction.

An insulator layer 30 is provided on the semiconductor substrate 20. The insulator layer 30 includes the peripheral circuit PERI corresponding to the row decoder module 15 and the like, for example.

The conductor layer 21 is laminated on the insulator layer 30. The conductor layer 21 is formed into a plate shape extending along an X-Y plane, for example. The conductor layer 21 is used as the source line SL. The conductor layer 21 is formed of a conductive material. For example, an impurity-doped N-type semiconductor or a metal material such as a compound (TiN) containing nitrogen and titanium, a compound (TaN) containing nitrogen and tantalum, a laminated film of aluminum (Al), a compound (TaN) containing nitrogen and tantalum, and tantalum (Ta), a laminated film of titanium (Ti), a compound (TiN) containing nitrogen and titanium, and tungsten (W), or a laminated film of a compound (TiN) containing nitrogen and titanium and silicide (WSi) containing tungsten and silicon is used. The conductor layer 21 may be a laminated structure of semiconductor and a metal material, such as a laminated film of a compound (TiN) containing nitrogen and titanium, silicide (WSi) containing tungsten and silicon, and polysilicon, for example.

An insulator layer 31 is provided on the conductor layer 21. The conductor layer 22 is laminated on the insulator layer 31. The conductor layer 22 is formed into a plate shape extending along the X-Y plane, for example. The conductor layer 22 is used as the select gate line SGS. The conductor layer 22 contains tungsten (W) or molybdenum (Mo), for example.

An insulator layer 32 is provided on the conductor layer 22. Eight conductor layers 23 and eight insulator layers 33 are laminated on the insulator layer 32 in the order of the conductor layer 23, the insulator layer 33, . . . , the conductor layer 23, and the insulator layer 33. The conductor layers 23 are formed into a plate shape extending along the X-Y plane, for example. The laminated eight conductor layers 23 are respectively used as the word lines WL0 to WL7 sequentially from the conductor layer 21 side. The conductor layers 23 contain tungsten (W) or molybdenum (Mo), for example.

The conductor layer 24 and an insulator layer 34 are laminated in this order on the uppermost insulator layer 33. The conductor layer 24 is formed into a plate shape extending along the X-Y plane, for example. The laminated conductor layer 24 is used as the select gate line SGD. The conductor layer 24 contains tungsten (W) or molybdenum (Mo), for example. The conductor layer 24 is electrically separated for each of the string units SU by a slit SHE, for example.

The insulator layer 34 is provided on the conductor layer 24. The conductor layer 25 is provided on the insulator layer 34. The conductor layer 25 is formed into a line shape extending in the Y-direction, for example, and functions as the bit line BL. The conductor layer 25 contains copper (Cu), for example.

The plurality of memory pillars MP are provided below the conductor layer 25 to extend in the Z-direction, and extends through the conductor layers 22 and 24 as well as the plurality of conductor layers 23. A bottom of each of the memory pillars MP is located in a layer below the insulator layer 31 and is in contact with the conductor layer 21.

Each of the memory pillars MP includes a core member 35, a semiconductor film 36, a tunnel insulation film 37, a charge accumulation film 38, a block insulation film 39, and a semiconductor portion 26, for example.

The core member 35 is provided to extend in the Z-direction, for example. An upper end of the core member 35 is included in a layer above the conductor layer 24, and a lower end of the core member 35 is included in a layer below the conductor layer 22. The core member 35 contains a compound (SiO2) containing oxygen and silicon, for example.

The semiconductor film 36 is provided to cover a side surface and a lower surface of the core member 35. An upper end of the semiconductor film 36 reaches a position comparable to the position of the upper end of the core member 35. A lower end of the semiconductor film 36 is in contact with the conductor layer 21. The semiconductor film 36 contains monocrystalline silicon or polysilicon, for example.

The tunnel insulation film 37 covers a side surface of the semiconductor film 36. The tunnel insulation film 37 contains a compound (SiO2) containing oxygen and silicon, for example.

The charge accumulation film 38 covers a side surface of the tunnel insulation film 37. The charge accumulation film 38 contains an insulator that can accumulate charge, for example. The insulator is a compound (SiN) containing nitrogen and silicon, for example.

The block insulation film 39 covers a side surface of the charge accumulation film 38. The block insulation film 39 contains a compound (SiO2) containing oxygen and silicon, for example.

The semiconductor portion 26 is provided to be in contact with the semiconductor film 36 and to cover the upper end of the core member 35. The conductor layer 27 that functions as a pillar-shaped contact CV is provided on an upper end of the semiconductor portion 26. An upper end of the conductor layer 27 is in contact with the conductor layer 25.

In the structure of the memory pillars MP described above, portions in which the memory pillars MP and the conductor layer 22 intersect with one another function as the select transistors ST2. Portions in which the memory pillars MP and the conductor layers 23 intersect with one another function as the memory cell transistors MT. Portions in which the memory pillars MP and the conductor layer 24 intersect with one another function as the select transistors ST1. The semiconductor film 36 functions as a channel of each of the memory cell transistors MT0 to MT7 as well as the select transistors ST1 and ST2. The charge accumulation film 38 functions as a charge accumulation layer of the memory cell transistors MT.

### 1.1.5 Row Decoder Module

A configuration example of the row decoder module 15 included in the peripheral circuit PERI will now be described.

### 1.1.5.1 Overall Configuration

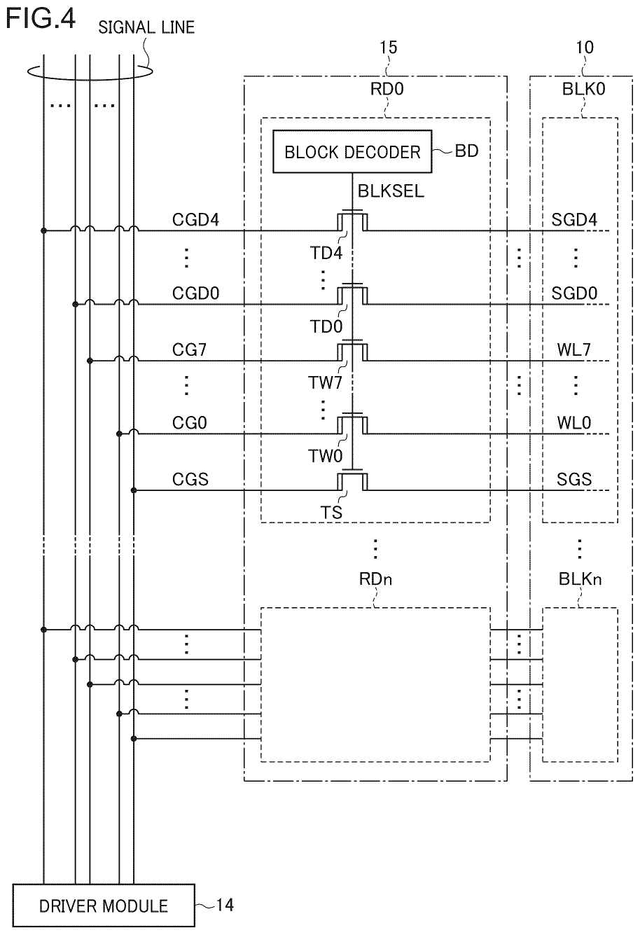

An overall configuration of the row decoder module 15 will be described using FIG. 4. FIG. 4 is a circuit diagram for describing an example of a configuration of the row decoder module, the driver module, and the memory cell array of the semiconductor storage device according to the embodiment.

The row decoder module 15 includes row decoders RD0 to RDn. The row decoders RD0 to RDn are used for selection of the block BLK. The row decoders RD0 to RDn are associated with the blocks BLK0 to BLKn, respectively.

Each of the row decoders RD includes the block decoder BD as well as transfer transistors TW0 to TW7, TS, and TD0 to TD4, for example. The transfer transistors TW0 to TW7, TS, and TD0 to TD4 are high-withstand voltage N-channel metal-oxide-semiconductor field effect transistors (MOSFETs), for example. The transfer transistors TW0 to TW7 are associated with the word lines WL0 to WL7, respectively. Note that in the following description, in a case in which the transfer transistors TW0 to TW7 are not distinguished from one another, they will simply be called a transfer transistor TW. The transfer transistor TS and TD0 to TD4 are associated with select gate lines SGS and SGD0 to SGD4, respectively. Note that in the following description, in a case in which the transfer transistors TD0 to TD4 are not distinguished from one another, they will simply be called a transfer transistor TD. A high-withstand voltage MOSFET refers to a MOSFET in which a gate insulation film has a physical film thickness more than or equal to 10 nm. A gate-source voltage of the high-withstand voltage N-channel MOSFET may be a voltage more than or equal to 10 V, for example.

The block decoder BD decodes the block address BA. The block decoder BD supplies a “H (High)”-level voltage and a “L (Low)”-level voltage to a transfer gate line BLKSEL based on a result of the decoding, for example.

The transfer transistors TW0 to TW7, TS, and TD0 to TD4 respectively connect the driver module 14 and the corresponding blocks BLK via signal lines CG0 to CG7, CGS, and CGD0 to CGD4. Note that in the following description, in a case in which the signal lines CG0 to CG7, CGS, and CGD0 to CGD4 are not distinguished from one another, they will simply be called a signal line CG.

More specifically, in each of the row decoders RD, a gate of the transfer transistor TD is connected to the transfer gate line BLKSEL. A first end of each of the transfer transistors TD is connected to the driver module 14 via a corresponding signal line CG among the signal lines CGD0 to CGD4. A second end of the transfer transistor TD is connected to a corresponding select gate line SGD among the select gate lines SGD0 to SGD4.

A gate of each of the transfer transistors TW is connected to the transfer gate line BLKSEL. A first end of each of the transfer transistors TW is connected to the driver module 14 via a corresponding signal line CG among the signal lines CG0 to CG7. A second end of each of the transfer transistors TW is connected to a corresponding word line WL among the word lines WL0 to WL7.

A gate of the transfer transistor TS is connected to the transfer gate line BLKSEL. A first end of the transfer transistor TS is connected to the driver module 14 via the signal line CGS. A second end of the transfer transistor TS is connected to the select gate line SGS.

In the case in which a “H”-level voltage is supplied to the transfer gate line BLKSEL, the transfer transistors TW, TS, and TD are brought into an on state. The voltages of the respective signal lines CG0 to CG7, CGS, and CGD0 to CGD4 are thereby transferred to the word lines WL0 to WL7, the select gate line SGS, and the select gate lines SGD0 to SGD4, respectively, via the transfer transistors TW0 to TW7, TS, and TD0 to TD4. In the case in which a “L”-level voltage is supplied to the transfer gate line BLKSEL, the transfer transistors TW, TS, and TD are brought into an off state.

### 1.1.5.2 Block Decoder

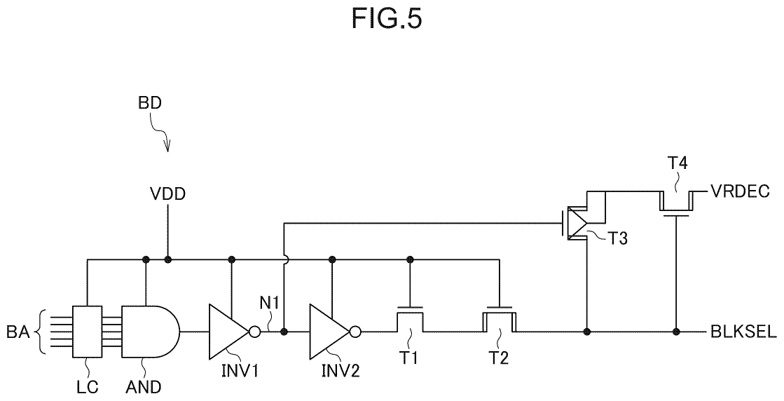

A configuration of the block decoder BD included in each of the row decoders RD will be described using FIG. 5. FIG. 5 is a circuit diagram for describing an example of the configuration of the block decoder included in the semiconductor storage device according to the embodiment.

As shown in FIG. 5, the block decoder BD includes a logic circuit LC, an AND circuit AND, inverters INV1 and INV2, and transistors T1, T2, T3, and T4. The transistors T1, T2, and T4 are N-channel MOSFETs. The transistor T3 is a P-channel MOSFET. The transistors T2, T3, and T4 are high-withstand voltage MOSFETs in which the gate insulation film has a physical film thickness larger than a physical film thickness of the gate insulation film of the transistor T1. The gate insulation film of each of the transistors T2, T3, and T4 has a physical film thickness more than or equal to 10 nm, for example. A gate-source voltage of each of the transistors T2, T3, and T4 may be a voltage more than or equal to 10 V, for example. On the other hand, the gate insulation film of the transistor T1 has a physical film thickness less than 10 nm, for example. A gate-source voltage of the transistor T1 is a voltage lower than 10 V, for example.

The block address BA is input to a first end of the logic circuit LC from the address register 12. A power supply voltage VDD is supplied to a second end of the logic circuit LC, for example. The logic circuit LC is driven by the power supply voltage VDD. A signal based on the block address BA is output from a third end of the logic circuit LC. In a case in which the block address BA input to the logic circuit LC is the block address BA allocated to the block BLK corresponding to the logic circuit LC, a “H”-level signal is output from the second end of the logic circuit LC. In a case in which the block address BA input to the logic circuit LC is not the block address BA allocated to the block BLK corresponding to the logic circuit LC, a “L”-level signal is output from the second end of the logic circuit LC.

A first end of the AND circuit AND is connected to a third end of the logic circuit LC. The power supply voltage VDD, for example, is supplied to a second end of the AND circuit AND. The AND circuit AND is driven by the power supply voltage VDD. A signal based on an AND operation of the signal output from the third end of the logic circuit LC is output from a third end of the AND circuit AND.

A first end of the inverter INV1 is connected to the third end of the AND circuit AND. The power supply voltage VDD, for example, is supplied to a second end of the inverter INV1. The inverter INV1 is driven by the power supply voltage VDD. A third end of the inverter INV1 is connected to a node N1. An inverted signal of the signal output from the third end of the AND circuit AND is output from the third end of the inverter INV1.

A first end of the inverter INV2 is connected to the node N1. The power supply voltage VDD, for example, is supplied to a second end of the inverter INV2. The inverter INV2 is driven by the power supply voltage VDD. An inverted signal of the signal output from the third end of the inverter INV1 is output from a third end of the inverter INV2.

A first end of the transistor T1 is connected to the third end of the inverter INV2. The power supply voltage VDD is supplied to a gate of the transistor T1. A second end of the transistor T1 is connected to the transistor T2.

A first end of the transistor T2 is connected to the second end of the transistor T1. The power supply voltage VDD is supplied to a gate of the transistor T2. A second end of the transistor T2 is connected to the transfer gate line BLKSEL.

A first end of the transistor T3 is connected to the transfer gate line BLKSEL. A gate of the transistor T3 is connected to the node N1. A second end of the transistor T3 is connected to a back gate of the transistor T3 and to the transistor T4.

A first end of the transistor T4 is connected to the second end of the transistor T3 and the back gate of the transistor T3. A gate of the transistor T4 is connected to the transfer gate line BLKSEL. A second end of the transistor T4 is connected to a node VRDEC. A high voltage which is set to be transferred to the transfer gate line BLKSEL via the transistors T3 and T4, thereby enabling the transfer transistors TW, TS, and TD to transfer voltages, to be supplied to the corresponding signal lines CG, to the word line WL, the select gate line SGS, and the select gate line SGD, respectively, is supplied to the node VRDEC.

With the configuration described above, the block decoder BD outputs a “H”-level signal to the transfer gate line BLKSEL in a case in which the corresponding block BLK is selected. The block decoder BD outputs a “L”-level signal to the transfer gate line BLKSEL in a case in which the corresponding block BLK is not selected.

### 1.1.5.3 Planar Configuration of Row Decoder Module

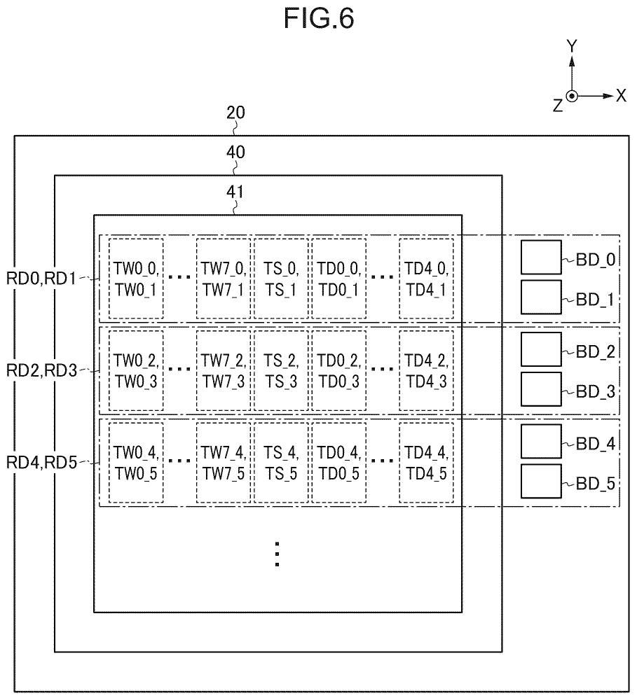

A planar structure of the row decoder module 15 of the semiconductor storage device 1 according to the embodiment will be described using FIG. 6. FIG. 6 is a plan view showing an example of the planar structure of the row decoder module of the semiconductor storage device according to the embodiment. Note that in the following description, the transfer transistors TW0 to TW7, TS, and TD0 to TD4 as well as the block decoder BD included in a row decoder RDi will also be called transfer transistors TW0_i to TW7_i, TS_i, and TD0_i to TD4_i as well as a block decoder BD_i, respectively, where i is an integer more than or equal to 0 and less than or equal to n.

The row decoder module 15 is provided on the semiconductor substrate 20.

The semiconductor substrate 20 is provided with an N-type well region 40. The N-type well region 40 is a region containing an N-type impurity. The N-type well region 40 is provided in a rectangular region, for example.

The N-type well region 40 is provided with a P-type well region 41. The P-type well region 41 is a region containing a P-type impurity. The P-type well region 41 is provided in a rectangular region, for example.

A set of row decoders RD(2j) and RD(2j+1) is provided in a rectangular region, for example, where j is an integer more than or equal to 0 and less than or equal to (n−1)/2.

A set of the row decoders RD0 and RD1, a set of row decoders RD2 and RD3, a set of row decoder RD4 and RD5, . . . are aligned in this order in the Y-direction, for example.

In the set of the row decoders RD(2j) and RD(2j+1), transfer transistors TS_(2j) and TS_(2j+1), TW0_(2j) and TW0_(2j+1), . . . , TW7_(2j) and TW7_(2j+1), TD0_(2j) and TD0_(2j+1), . . . , as well as TD4_(2j) and TD4_(2j+1) are each provided in the P-type well region 41, for example.

In the set of the row decoders RD(2j) and RD(2j+1), block decoders BD_(2j) and BD_(2j+1) are provided outside the N-type well region 40, for example.

Note that a set of a plurality of transfer transistors TW_(2j) and TW_(2j+1), a set of TS_(2j) and TS_(2j+1), as well as a set of TD_(2j) and TD_(2j+1) are provided in a matrix shape aligned in each of the X-direction and the Y-direction, for example.

### 1.1.5.4 Transfer Transistors

A configuration of the transfer transistors TW, TS, and TD included in the semiconductor storage device 1 according to the embodiment will be described.

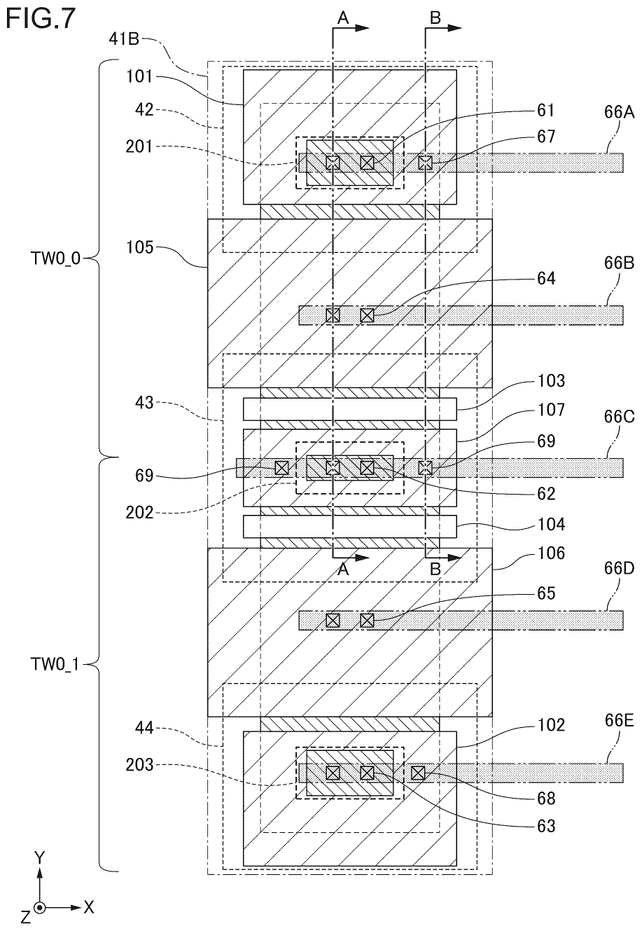

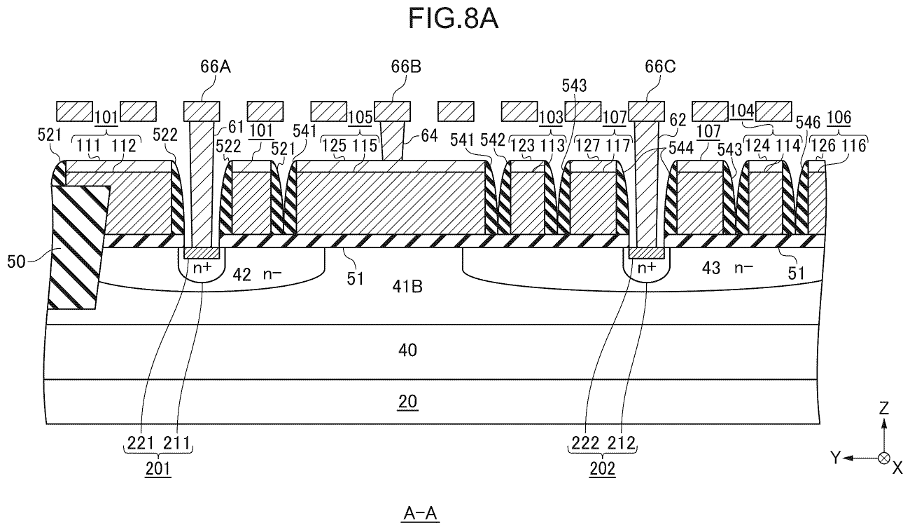

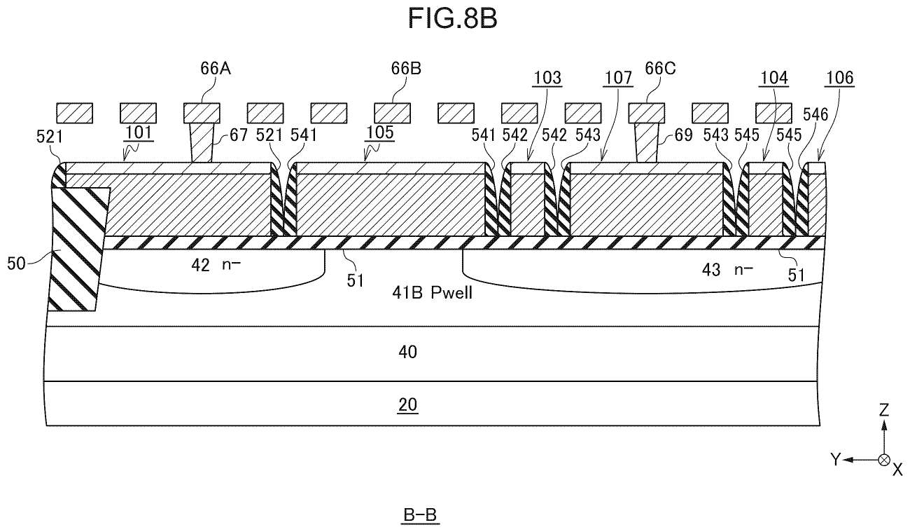

A planar structure of the transfer transistors TW, TS, and TD will be described using FIG. 7, FIG. 8A, and FIG. 8B. FIG. 7 is a plan view showing an example of the planar structure of the transfer transistors included in the semiconductor storage device according to the embodiment. FIG. 8A is a cross-sectional view taken along the line A-A which is perpendicular to the X-direction, is parallel to the Z-direction, and has been cut along an imaginary plane passing through a contact 61 and a contact 62 in FIG. 7. FIG. 8B is a cross-sectional view taken along the line B-B which is perpendicular to the X-direction, is parallel to the Z-direction, and has been cut along an imaginary plane passing through a contact 67 and a contact 69 in FIG. 7.

In the example shown in FIG. 7, the planar structure including transfer transistors TW0_0 and TW0_1 in the configuration shown in FIG. 6 is mainly shown. A structure of the set of the transfer transistors TW_(2j) and TW_(2j+1), a structure of the set of TS_(2j) and TS_(2j+1), and a structure of the set of TD_(2j) and TD_(2j+1) have a structure substantially comparable to one another. Hereinafter, the structure of the transfer transistors TW0_0 and TW0_1 will be mainly described.

An insulator layer 50 provided as an element isolation region formed into a grid shape, for example, is formed on the P-type well region 41 (which will be called an “element region” in some cases) shown in FIG. 6. In the present embodiment, a partial region of the P-type well region 41 formed on the entire surface of the row decoder module 15 will be called a P-type well region 41B and is shown as a region enclosed by a dash-dotted line in the plan view shown in FIG. 7. Respective regions surrounded (enclosed) by the insulator layer 50 formed on the P-type well region 41B and formed into a grid shape are each equivalent to an active region AA. The plurality of transfer transistors TW, TS, TD, and the like may be formed in each of the active regions AA.

As shown in FIG. 7, the transfer transistors TW0_0 and TW0_1 are provided to align in this order in the Y-direction. Note that in the following description, of the transfer transistors TW0_0 and TW0_1, an end at which the transfer transistor TW0_0 is provided will be called one end in some cases, and of the transfer transistors TW0_0 and TW0_1, an end at which the transfer transistor TW0_1 is provided will be called the other end in some cases.

As shown in FIG. 7, an N-impurity diffusion region 42, an N-impurity diffusion region 43, and an N-impurity diffusion region 44 are provided in this order in the Y-direction (an example of a “first direction”) separately from each other. The N-impurity diffusion region 42, the N-impurity diffusion region 43, and the N-impurity diffusion region 44 are N-type impurity diffusion regions in which phosphorus (P), arsenic (As), or the like as a dopant, for example, has been diffused.

An electrode 201 is provided in the N-impurity diffusion region 42, an electrode 202 is provided in the N-impurity diffusion region 43, and an electrode 203 is provided in the N-impurity diffusion region 44. Regions in which the electrode 201, the electrode 202, and the electrode 203 are provided are regions enclosed by broken lines in FIG. 7.

The electrode 201 functions as a first end of the transfer transistor TW0_0. The electrode 203 functions as a first end of the transfer transistor TW0_1. The electrode 202 functions as a second end of the transfer transistor TW0_0 and a second end of the transfer transistor TW0_1. In this manner, the transfer transistors TW0_0 and TW0_1 share the electrode 202.

The electrode 201 is a region which is equivalent to a region connected to a lower end of the contact 61 and which is to be a source region or a drain region (an example of a “first region”) of the transfer transistor TW0_0. The electrode 201 includes a region (which will be called an “N+ impurity diffusion region 201” in some cases) having an impurity concentration higher than an impurity concentration of the N-impurity diffusion region 42. In other words, the N-impurity diffusion region 42 (an example of a “first high-resistance diffusion layer”) is a high-resistance diffusion layer that surrounds the electrode 201 which is the source region or the drain region and that has a relatively higher resistance because of having the impurity concentration lower than the impurity concentration of the N+ impurity diffusion region to be the electrode 201. In the present embodiment, the electrode 201 may include a conductor layer 221 connected to the lower end of the contact 61 and containing silicide, and an N+ impurity diffusion region 211 (FIG. 8A). However, this is not a limitation, and the electrode 201 may not contain silicide, for example.

The electrode 202 is a region which is equivalent to a region connected to a lower end of the contact 62 and which is to be the drain region or the source region (an example of a “second region”) of the transfer transistors TW0_0 and TW0_1. The electrode 202 includes a region (which will be called an “N+ impurity diffusion region 202” in some cases) having an impurity concentration higher than an impurity concentration of the N− impurity diffusion region 43. In other words, the N− impurity diffusion region 43 (an example of a “second high-resistance diffusion layer”) is a high-resistance diffusion layer that surrounds the electrode 202 which is the source region or the drain region and that has a relatively higher resistance because of having the impurity concentration lower than the impurity concentration of the N+ impurity diffusion region to be the electrode 202. In the present embodiment, the electrode 202 may include a conductor layer 222 connected to the lower end of the contact 62 and containing silicide, and an N+ impurity diffusion region 212 (FIG. 8A). However, this is not a limitation, and the electrode 202 may not contain silicide, for example.

The electrode 203 is a region which is equivalent to a region connected to a lower end of a contact 63 and which is to be the source region or the drain region (an example of a “first region”) of the transfer transistor TW0_1. The electrode 203 includes a region (which will be called an “N+ impurity diffusion region 203” in some cases) having an impurity concentration higher than an impurity concentration of the N− impurity diffusion region 44. In other words, the N− impurity diffusion region 44 (an example of the “second high-resistance diffusion layer”) is a high-resistance diffusion layer that surrounds the electrode 203 which is the source region or the drain region and has a relatively higher resistance because of having the impurity concentration lower than the impurity concentration of the N+ impurity diffusion region to be the electrode 203. In the present embodiment, the electrode 203 may include a conductor layer 223 connected to the lower end of the contact 63 and containing silicide, and an N+ impurity diffusion region 213 (FIG. 8A). However, this is not a limitation, and the electrode 203 may not contain silicide, for example.

As shown in FIG. 8A which is the cross-sectional view taken along the line A-A in FIG. 7, the contact 61 (an example of a “first contact”) connected at the lower end to the electrode 201, extending upward from the electrode 201, and connected at an upper end to a conductor layer 66A (an example of a “first wiring layer”) extending in the X-direction is formed on the electrode 201. The conductor layer 66A is connected to the word line WL0 of the block BLK0 connected to the control gate of the memory cell transistor MT0 (an example of a “first memory cell”) of the block BLK0.

The contact 62 (an example of a “second contact”) connected at the lower end to the electrode 202, extending upward from the electrode 202, and connected at an upper end to a conductor layer 66C extending in the X-direction is formed on the electrode 202. The conductor layer 66C is connected to the signal line CG0.

The contact 63 (an example of the “first contact”) connected at the lower end to the electrode 203, extending upward from the electrode 203, and connected at an upper end to a conductor layer 66E (an example of the “first wiring layer”) extending in the X-direction is further formed on the electrode 203. The conductor layer 66E is connected to the word line WL0 of the block BLK1 connected to the control gate of the memory cell transistor MT0 (an example of the “first memory cell”) of the block BLK1.

Note that FIG. 7 shows an example in which the number of contacts provided for each of the electrode 201, the electrode 202, and the electrode 203 is two, but this is not a limitation. The number of contacts provided for each of the electrode 201, the electrode 202, and the electrode 203 may be one, or three or more.

As shown in FIG. 8A, an electrode 101, an electrode 105, an electrode 103, an electrode 107, an electrode 104, an electrode 106, and an electrode 102 which are seven conductors are formed above the semiconductor substrate 20 in the Z-direction, that is, above the electrode 201, the electrode 202, and the electrode 203 including the N+ impurity diffusion regions formed on the semiconductor substrate 20 and below the conductor layer 66A (and the upper end of the contact 61 connected thereto), the conductor layer 66C (and the upper end of the contact 62 connected thereto), and the conductor layer 66E (and the upper end of the contact 63 connected thereto). The electrode 101, the electrode 105, the electrode 103, the electrode 107, the electrode 104, the electrode 106, and the electrode 102 are provided in this order in the Y-direction, for example.

In the Z-direction, at least some of the electrode 101, the electrode 105, the electrode 103, the electrode 107, the electrode 104, the electrode 106, and the electrode 102 each include portions formed at a height equal to each other. Therefore, the conductor layers 66A to 66E are formed above these respective electrodes.

In the present embodiment, in order to achieve such a configuration, the respective electrodes are each formed on insulation film 51 having an equal thickness and an equal composition because of being deposited in the same process, and the electrodes themselves have an equal thickness and an equal composition because of being formed in the same process. In addition, in the present embodiment, sidewalls having an equal composition are respectively formed on lateral walls constituting an outer circumferential surface and an inner circumferential surface of each of the electrodes. However, the sidewalls of each of the electrodes may not necessarily be formed. Hereinafter, a configuration of each of the electrodes will be described.

The electrode 101 (an example of a “first conductor”) is a conductor formed at a height equal to a height of the electrode 105 which is a gate electrode in the Z-direction and having at least a portion provided between the contact 61 and the electrode 105 in the Y-direction. The electrode 101 is formed on the insulation film 51.

An upper surface of the electrode 101 is connected to a lower end of the contact 67 (an example of a “third contact”). An upper end of the contact 67 and the upper end of the contact 61 are each connected to the conductor layer 66A. Therefore, the electrode 101 is configured to be electrically connected to the contact 61 via the contact 67 and the conductor layer 66A and to have a potential substantially equal to the potential of the contact 61 and the electrode 201. On the other hand, the electrode 101 is insulated from the electrode 105, and is electrically connected to the contact 62 when the transfer transistor TW0_0 is on and insulated from the contact 62 when the transfer transistor TW0_0 is off.

Such a configuration can reduce variation in potential in the diffusion layer including the electrode 201 in the semiconductor substrate 20 by causing the electrode 101 provided above the semiconductor substrate 20 and below a conductor layer such as the conductor layer 66B to function as a shield when a high voltage is supplied to the conductor layer such as the conductor layer 66B, for example.

Note that the electrode 101 may include a conductor layer 111 containing polysilicon or the like and a conductor layer 121 formed on an upper surface of the conductor layer 111 and containing, for example, silicide (NiSi) containing nickel and silicon, silicide (NiPtSi) containing nickel, platinum, and silicon, silicide (CoSi) containing cobalt and silicon, or the like.

Herein, the electrode 101 of the present embodiment is opposed to the N− impurity diffusion region 42 with the insulation film 51 interposed therebetween in the Z-direction as shown in FIG. 8A, for example. In other words, the insulation film 51 is provided between the electrode 101 and the N− impurity diffusion region 42 which is a high-resistance diffusion layer.

With such a configuration, when a voltage is supplied to each of the electrode 201 and the gate electrode 105 to turn on the transfer transistor TW0_0, the voltage is also supplied to the electrode 101. This can cause an electric field to act from the electrode 101 on the N− impurity diffusion region 42 opposed in the Z-direction with the insulation film 51 interposed therebetween. Thus, an on-resistance of the transfer transistor TW0_0 can be lowered.

As shown in FIG. 7, the electrode 101 in the present embodiment further has an opening that opens so as to enclose the contact 61. In other words, the contact 61 is formed to extend in the Z-direction so as to extend through the opening formed in the electrode 101 and to be connected at the lower end to the electrode 201.

With such a configuration, the electrode 101 is formed so as to surround the contact 61 connected to the electrode 201. This can further reduce variation in potential in the diffusion layer in the semiconductor substrate 20 including the electrode 201, which results from the conductor layer 66B and the like.

Note that a sidewall 521 is provided on each lateral wall constituting the outer circumferential surface of the electrode 101, and a sidewall 522 is provided on a lateral wall constituting the inner circumferential surface.

The electrode 105 (an example of a “gate electrode”) is a gate electrode of the transfer transistor TW0_0. The electrode 105 is provided between the contact 61 connected to the electrode 201 which is the source region or the drain region and the contact 62 connected to the electrode 202 which is the drain region or the source region in the Y-direction. The electrode 105 is formed on the insulation film 51 (which will also be called the “gate insulation film 51” in some cases).

An upper surface of the electrode 105 is connected to a lower end of the contact 64. An upper end of the contact 64 is connected to the conductor layer 66B constituting a portion of the transfer gate line BLKSEL for supplying a gate signal of the transfer transistor TW0_0.

Note that the electrode 105 may include a conductor layer 115 containing polysilicon or the like and a conductor layer 125 formed on an upper surface of the conductor layer 115 and containing silicide (NiSi) containing nickel and silicon, silicide (NiPtSi) containing nickel, platinum, and silicon, silicide (CoSi) containing cobalt and silicon, or the like, for example. A sidewall 541 (an example of a “gate electrode sidewall”) may be provided on each lateral wall constituting the outer circumferential surface of the electrode 105.

As shown in FIG. 7, a narrow slit extending in the X-direction (the direction perpendicular to a channel direction of the transfer transistor TW0_0) is formed between the electrode 105 and the electrode 101.

Therefore, the most part of the region of the surface of the semiconductor substrate 20 located below the conductor layer 66A and the conductor layer 66B excluding the opening and the slit through which the contact 61 extends is covered by the electrode 101 and the electrode 105.

Such a configuration can reduce variation in potential in the diffusion layer including the electrode 201 in the semiconductor substrate 20 by causing at least one of the electrode 101 and the electrode 105 provided above the semiconductor substrate 20 and below a conductor layer such as the conductor layer 66A to function as a shield when a high voltage is supplied to the conductor layer such as the conductor layer 66A, for example.

Herein, as shown in FIG. 8A, a portion of the sidewall 521 formed on the lateral wall of the electrode 101 in the present embodiment and a portion of the sidewall 541 formed on the lateral wall of the electrode 105 are in contact with each other at least in a lower region in the slit. Thus, at least a portion of the slit is plugged up.

Such a configuration enables the most part of the region in the slit to be plugged up and the region in the opening of the electrode 101 and the like to be exposed. Thus, the conductor layer 221 or the like containing silicide can be selectively provided in the region in the opening through use of a self-alignment process.

The electrode 103 (an example of a “second conductor”) shown in FIG. 7 is a conductor formed at a height equal to the height of the electrode 105 which is a gate electrode in the Z-direction, having at least a portion formed between the electrode 105 which is the gate electrode and the contact 62 which is the second contact in the Y-direction, and insulated from all of the electrode 105, the contact 61, and the contact 62.

The electrode 103 in the present embodiment is a floating electrode and has a circumference surrounded by an insulator. In the present embodiment, it can be said that the electrode 103 is provided between the electrode 105 which is the gate electrode and the electrode 107 because the electrode 107 in which an opening that surrounds the contact 62 is formed is provided.

As will be described later, the inventors of the present application have found that, by providing the electrode 103 which is the conductor insulated from all of the electrode 105, the contact 61, and the contact 62 between the electrode 105 which is the gate electrode and the contact 62 which is the second contact, a withstand voltage in a case in which a large potential difference is produced between the electrode 105 and the electrode 202 (and the contact 62 connected thereto) can be raised as compared with a case in which the electrode 103 is not provided.

However, the electrode 103 does not necessarily need to be a floating electrode as long as it is insulated from all of the electrode 105, the contact 61, and the contact 62 and may be configured to have a constant potential, for example. In order to achieve such a configuration, the electrode 103 may be connected to a conductor layer (an example of a “constant potential wiring layer”) for supplying a constant potential, for example.

Such a configuration can also raise the withstand voltage even in the case in which a large potential difference is produced between the electrode 105 and the electrode 202 (and the contact 62 connected thereto).

Note that the potential supplied to the electrode 103 may be higher than one of potentials when a large potential difference is produced between the electrode 105 and the electrode 202 and lower than the other potential. For example, when 0 V is supplied to the electrode 105 and when a voltage more than or equal to 20 V is supplied to the electrode 202, the potential supplied to the electrode 103 may be 5 to 15 V, for example.

The electrode 103 may include a conductor layer 113 containing polysilicon or the like and a conductor layer 123 formed on an upper surface of the conductor layer 113 and containing silicide, and a sidewall 542 (an example of a “second sidewall”) may be provided on each lateral wall constituting the outer circumferential surface, similarly to the electrode 105.

As shown in FIG. 7, a narrow slit extending in the X-direction (the direction perpendicular to the channel direction of the transfer transistor TW0_0) is formed between the electrode 105 and the electrode 103. As shown in FIG. 8A, a portion of the sidewall 542 formed on the lateral wall of the electrode 103 of the present embodiment and a portion of the sidewall 541 formed on the lateral wall of the electrode 105 are in contact with each other at least in a lower region in the slit. Thus, at least a portion of the slit is plugged up.

Such a configuration enables the most part of the region in the slit to be plugged up and the region in the opening of the electrode 101 and the like to be exposed. Thus, the conductor layer 221 or the like containing silicide can be selectively provided in the region in the opening through use of the self-alignment process.

The electrode 107 (an example of a “third conductor”) is a conductor formed at a height equal to the height of the electrode 105 and the electrode 106 which are gate electrodes in the Z-direction and provided between the electrode 105 and the electrode 106 which are two gate electrodes in the Y-direction. Therefore, the electrode 103 is formed between the electrode 107 and the electrode 105. The electrode 107 is formed on the insulation film 51.

An upper surface of the electrode 107 is connected to a lower end of the contact 69 (an example of a “fourth contact”). An upper end of the contact 69 and the upper end of the contact 62 are each connected to the conductor layer 66C. Therefore, the electrode 107 is electrically connected to the contact 62 with the contact 69 and the conductor layer 66C interposed therebetween and is configured to have a potential substantially equal to the potential of the contact 62 and the electrode 202. On the other hand, the electrode 107 is insulated from the electrode 105 and is electrically connected to the contact 63 when the transfer transistor TW0_1 is on and insulated from the contact 63 when transfer transistor TW0_1 is off.

Such a configuration can reduce variation in potential in the diffusion layer including the electrode 202 in the semiconductor substrate 20 by causing the electrode 107 provided above the semiconductor substrate 20 and below a conductor layer such as the conductor layer 66B to function as a shield when a high voltage is supplied to the conductor layer such as the conductor layer 66B, for example.

Note that the electrode 107 may include a conductor layer 117 containing polysilicon or the like, and a conductor layer 127 formed on an upper surface of the conductor layer 117 and containing silicide (NiSi) containing nickel and silicon, silicide (NiPtSi) containing nickel, platinum, and silicon, silicide (CoSi) containing cobalt and silicon, or the like, for example.

Herein, the electrode 107 of the present embodiment is opposed to an N− impurity diffusion region 43 (an example of the “second high-resistance diffusion layer”) with the insulation film 51 interposed therebetween in the Z-direction as shown in FIG. 8A, for example. In other words, the insulation film 51 is provided between the electrode 107 and the N− impurity diffusion region 43 which is a high-resistance diffusion layer.

With such a configuration, when a voltage is supplied to each of the electrode 202 and the gate electrode 105 to turn on the transfer transistor TW0_0, the voltage is also supplied to the electrode 107. This can cause an electric field to act from the electrode 107 on the N− impurity diffusion region 43 opposed in the Z-direction with the insulation film 51 interposed therebetween. Thus, the on-resistance of the transfer transistor TW0_0 can be lowered.

As shown in FIG. 7, the electrode 107 in the present embodiment further has an opening that opens so as to enclose the contact 62. In other words, the contact 62 is formed to extend in the Z-direction so as to extend through the opening formed in the electrode 107 and to be connected at the lower end to the electrode 202.

With such a configuration, the electrode 107 is formed so as to surround the contact 62 connected to the electrode 202. This can further reduce variation in potential in the diffusion layer in the semiconductor substrate 20 including the electrode 202, which results from the conductor layer 66B and the like.

Note that a sidewall 543 (an example of a “third sidewall”) is provided on each lateral wall constituting the outer circumferential surface of the electrode 107, and a sidewall 544 is provided on a lateral wall constituting the inner circumferential surface opposed to the contact 62.

As shown in FIG. 7, a narrow slit extending in the X-direction (the direction perpendicular to the channel direction of the transfer transistor TW0_0) is formed between the electrode 103 and the electrode 107. As shown in FIG. 8A, a portion of the sidewall 542 formed on the lateral wall of the electrode 103 of the present embodiment and a portion of the sidewall 543 formed on the lateral wall of the electrode 107 are in contact with each other at least in a lower region in the slit. Thus, at least a portion of the slit is plugged up.

Such a configuration enables the most part of the region in the slit to be plugged up and the region in the opening of the electrode 101 and the like to be exposed. Thus, the conductor layer 221 or the like containing silicide can be selectively provided in the region in the opening through use of the self-alignment process.

In the present embodiment, the transfer transistor TW0_0 and the transfer transistor TW0_1 are formed symmetrically with the conductor layer 66C extending in the X-direction serving as an axis as shown in FIG. 7 and the like. Therefore, description of the configuration of the transfer transistor TW0_1 will be simplified.

The electrode 104 (an example of the “second conductor”) is a conductor including a configuration similar to the configuration of the electrode 103, formed at a height equal to the height of the electrode 106 which is the gate electrode in the Z-direction, having at least a portion formed between the electrode 106 which is the gate electrode and the contact 62 which is the second contact in the Y-direction, and insulated from all of the electrode 106, the contact 63, and the contact 62. Similarly to the electrode 103, the electrode 104 may be configured as a floating electrode, or may be configured to have a constant potential by being connected to the conductor layer (an example of the “constant potential wiring layer”) for supplying a constant potential. One of ordinary skill in the art will understand that the remaining configuration including a sidewall 545 formed on the electrode 104 and technical effects associated with provision of the electrode 104 are similar to those of the electrode 103, and description thereof will thus be omitted.

The electrode 106 (an example of the “gate electrode”) is the gate electrode of the transfer transistor TW0_1, which includes a configuration similar to the configuration of the electrode 105. The electrode 106 is provided between the contact 63 connected to the electrode 203 which is the source region or the drain region and the contact 62 connected to the electrode 202 which is the drain region or the source region in the Y-direction. The electrode 106 is formed on the insulation film 51 (which will be called the “gate insulation film 51” in some cases). An upper surface of the electrode 106 is connected to a lower end of the contact 65, and an upper end of the contact 65 is connected to the conductor layer 66D constituting a portion of the transfer gate line BLKSEL for supplying a gate signal of the transfer transistor TW0_1. Note that the electrode 106 may include a conductor layer 116 and a conductor layer 126, and a sidewall 546 (an example of the “gate electrode sidewall”) may be provided on each lateral wall constituting the outer circumferential surface of the electrode 106.

The electrode 102 (an example of the “first conductor”) shown in FIG. 7 is a conductor including a configuration similar to the configuration of the electrode 101, formed at a height equal to the height of the electrode 106 which is the gate electrode in the Z-direction, and having at least a portion provided between the contact 63 and the electrode 106 in the Y-direction. The electrode 102 is formed on the insulation film 51, and an upper surface of the electrode 102 is connected to a lower end of a contact 68 (an example of the “third contact”), and an upper end of the contact 68 and the upper end of the contact 63 are each connected to the conductor layer 66E. Thus, the electrode 102 is configured to have a potential substantially equal to the potential of the contact 63 and the electrode 203. On the other hand, the electrode 102 is insulated from the electrode 106 and is electrically connected to the contact 62 when the transfer transistor TW0_1 is on and insulated from the contact 62 when the transfer transistor TW0_1 is off. One of ordinary skill in the art will understand that the remaining configuration of the electrode 102 and technical effects associated with provision of the electrode 102 are similar to those of the electrode 101, and description thereof will thus be omitted.

Similarly to the transfer transistor TW0_0, a narrow slit extending in the X-direction (the direction perpendicular to the channel direction of the transfer transistor TW0_1) is formed between the respective electrodes constituting the transfer transistor TW0_1, and a portion of the sidewall formed on the lateral wall of each of the electrodes and a portion of the sidewall formed on the lateral wall of an opposed electrode are in contact with each other at least in a lower region in the slit. Thus, at least a portion of the slit is plugged up, which enables silicide or the like to be provided selectively in the region in the opening of the electrode 106.

Note that a shield conductor layer containing polysilicon, for example, may be provided on the insulator layer 50 so as to enclose the active region AA, for example. The shield conductor layer may be provided in a grid shape similarly to the insulator layer 50, and sidewalls may be provided on side surfaces on the inner circumference and outer circumference. A space above the semiconductor substrate 20 is filled with an insulator (not shown) formed of an oxide insulation film or the like for insulating the conductor layers such as the conductor layer 66A from each other and the respective electrodes from each other.

With the configuration described above, in the transfer transistor TW0_0, the electrode 101 which is the first conductor is provided at a height equal to the height of the gate electrode 105 above the semiconductor substrate 20 and below the conductor layer 66A, and the electrode 101 and the contact 61 which is the first contact connected to the source region or the drain region are electrically connected to each other. Thus, the electrode 101 serves as a shield, which can reduce voltage variation in the source region or the drain region, which results from an overlying conductor layer such as the conductor layer 66B.

In addition, the electrode 103 insulated from all of the gate electrode 105, the contact 61, and the contact 62 is provided above the semiconductor substrate 20, below the conductor layer 66A, and between the gate electrode 105 and the contact 62. This can raise the withstand voltage for the potential difference between the electrodes. Hereinafter, this point will be described.

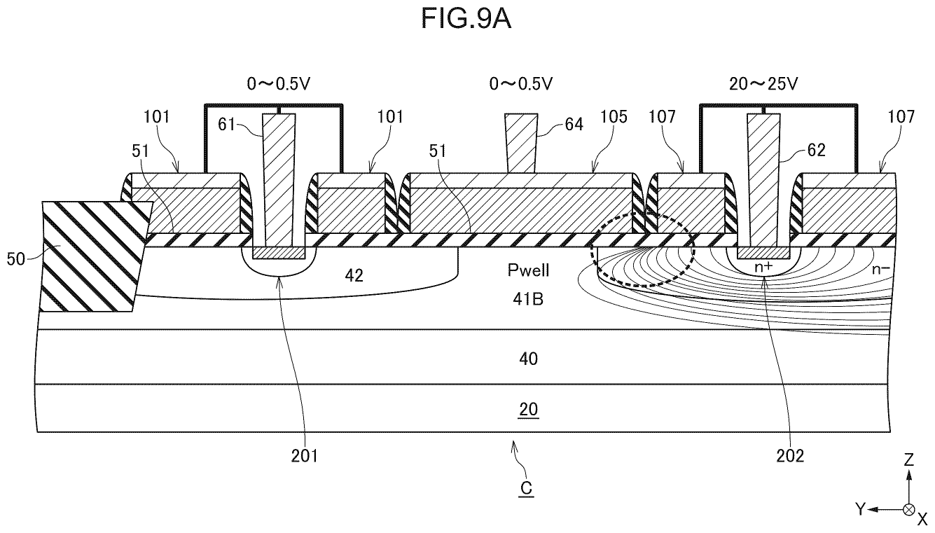

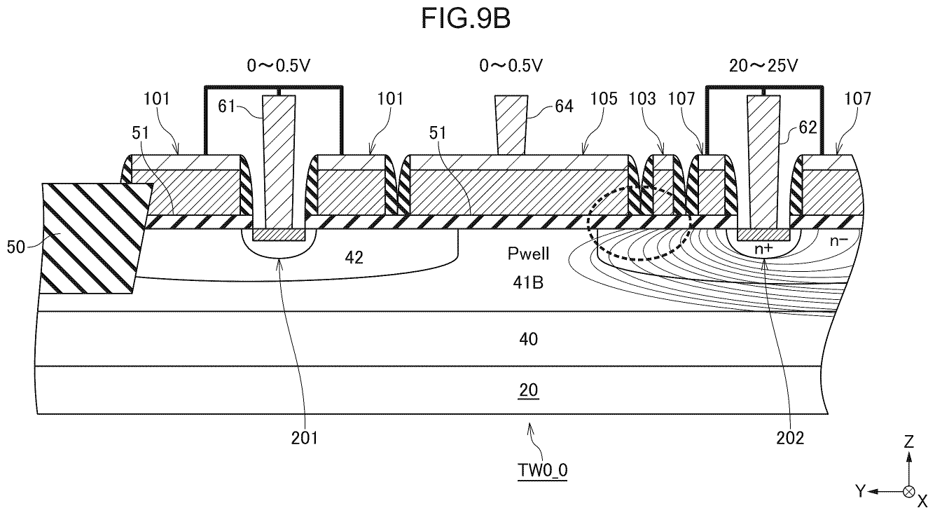

FIG. 9A is a schematic view showing lines of electric force during cutoff in a transfer transistor C according to the comparative example, and FIG. 9B is a schematic view showing lines of electric force during cutoff in the transfer transistor TW0_0 according to the present embodiment. Note that for ease of description, common or alike components will be denoted by the same reference character, and description thereof will be omitted. A wire connecting a contact and an electrode schematically shows that the contact and the electrode have substantially equal potentials, and traces are omitted. Other components are also simplified as appropriate.

As shown in FIG. 9A and FIG. 9B, the transfer transistor C according to the comparative example is different from the transfer transistor TW0_0 in that a component equivalent to the electrode 103 is not provided, and instead the electrode 107 extends to a position opposed to the electrode 105.

In a case in which a predetermined transfer transistor is cut off when a NAND flash memory is programmed, a high voltage (e.g., 20 to 25 V) is supplied to the signal line CG, and a low voltage (e.g., 0 to 0.5V) is supplied to the word line WL and the gate electrode 105. Therefore, a potential difference more than or equal to 20 V is produced between the gate electrode 105 and both the contact 62 and the electrode 202 connected to the signal line CG. Thus, a withstand voltage between both the electrodes becomes an issue.

The inventors of the present application have found out that in the transfer transistor C according to the comparative example, equipotential lines concentrate on a lower end portion of a slit formed between the electrode 107 and the electrode 105 to produce a region with steep variation in electric field as shown in FIG. 9A, resulting in deterioration in withstand voltage.

On the other hand, as shown in FIG. 9B, the transfer transistor TW0_0 according to the present embodiment includes the electrode 103 between the gate electrode 105 and the contact 62, the electrode 103 being insulated from all of the gate electrode 105, the contact 61, and the contact 62 and being floating or having a constant potential (herein, the “constant potential” including a potential in a constant range; preferably, 5 to 15 V which is an intermediate potential, for example) supplied thereto.

With such a configuration, both ends of the electrode 103 in the Y-direction are insulated from the other adjacent electrodes. This can mitigate the concentration of equipotential lines to therefore raise the withstand voltage.

Note that a plurality of components equivalent to the electrode 103 may be provided. The components equivalent to the electrode 103 may be provided on the electrode 201 side. Although an example in which the present embodiment is applied to the transfer transistor TW0_0 has been described, the present embodiment can be applied to another transfer transistor such as the transfer transistor TS or the transfer transistor TD. Alternatively, the present embodiment can be applied to another transistor that requires a withstand voltage. In addition, the electrodes such as the electrode 103 can be variously modified in shape.

Besides, the present disclosure is not limited to these specific examples. Configurations obtained by one of ordinary skill in the art adding appropriate design changes to these specific examples are also involved in the scope of the present disclosure as long as they include features of the present disclosure. Hereinafter, another embodiment will be described. Note that components common or alike to the components of the present embodiment are denoted by the same or alike reference characters, and description thereof will be simplified or omitted as appropriate. Different points will be mainly described.

### 2 Second Embodiment

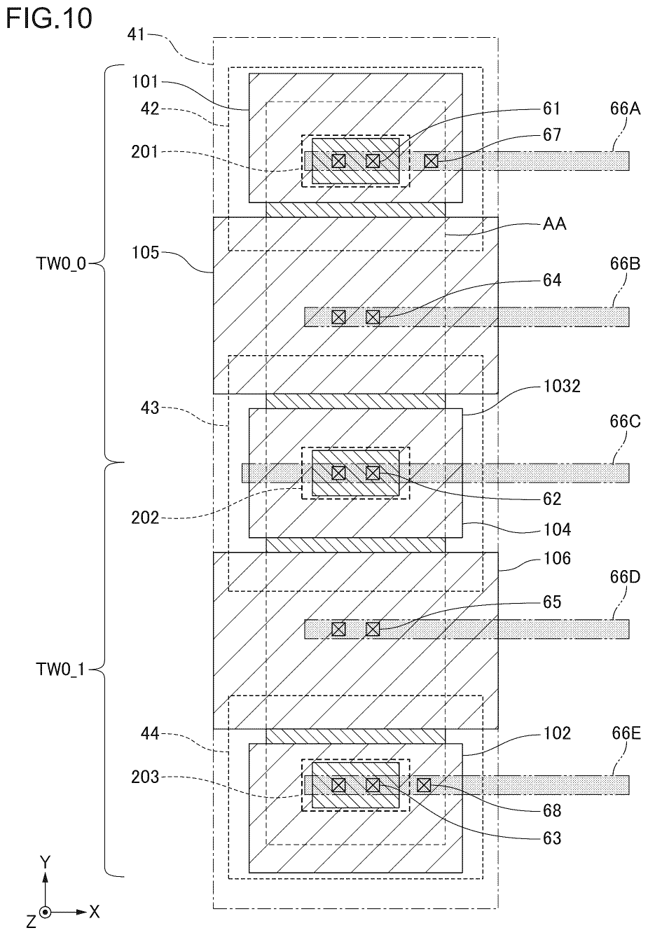

FIG. 10 shows the transfer transistor TW0_0 and a transfer transistor TW1_1 according to the present embodiment. The transfer transistors of the present embodiment are different from the transfer transistors according to the first embodiment in that the electrode 107 is not provided and in that an electrode 1032 equivalent to the electrode 103 has a different shape.

The electrode 1032 (an example of the “second conductor”) of the transfer transistor TW0_0 and the transfer transistor TW1_1 according to the present embodiment is provided so as to surround the contact 62 which is the second contact. Herein, the electrode 1032 is insulated from all of the contact 61 which is the first contact, the contact 62, and the electrode 105 which is the gate electrode. The electrode 1032 may be floating, or a potential in a constant range (preferably, an intermediate potential of potentials that may be supplied to both electrodes) may be supplied to the electrode 1032.

Also with such a configuration, the outer circumference of the electrode 1032 and the inner circumference in the Y-direction opposed to the contact 62 are each insulated from the other adjacent electrodes. This can mitigate the concentration of equipotential lines to therefore raise the withstand voltage.

### 3 Third Embodiment

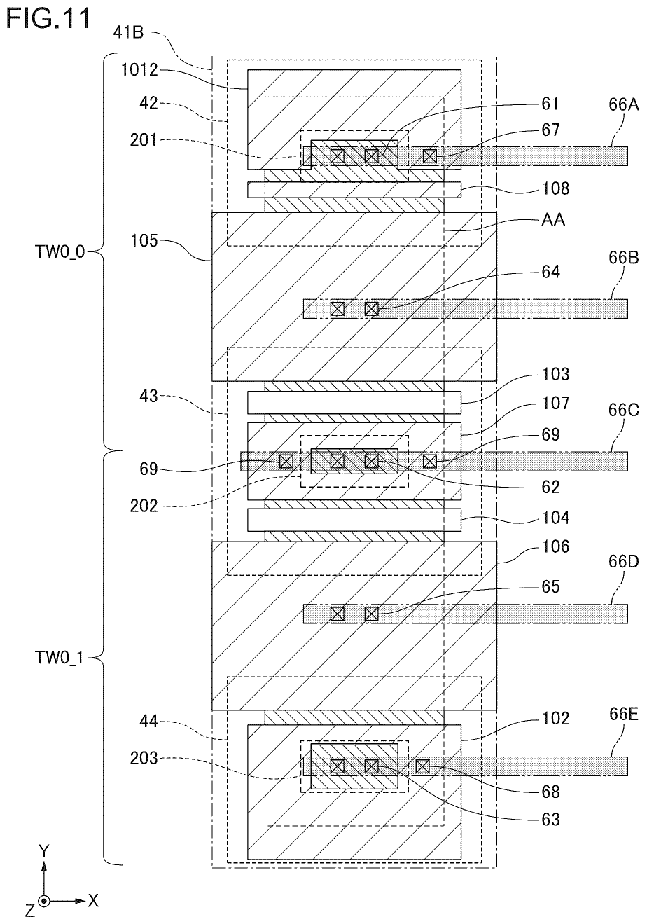

FIG. 11 shows the transfer transistor TW0_0 and the transfer transistor TW1_1 according to the present embodiment. The transfer transistors of the present embodiment are different from the transfer transistors according to the first embodiment in that an electrode 108 (an example of a “fourth conductor”) is provided and in that an electrode 1012 (an example of the “first conductor”) equivalent to the electrode 101 has a different shape.

The electrode 108 has a height equal to the height of the gate electrode 105, has at least a portion formed between the gate electrode 105 and the contact 61 which is the first contact, and is insulated from the gate electrode 105, the contact 61, and the contact 62 which is the second contact.

With such a configuration, both ends of the electrode 108 in the Y-direction are insulated from the other adjacent electrodes. This can mitigate the concentration of equipotential lines to therefore also raise the withstand voltage based on the potential difference between the second end and the gate electrode 105.

A configuration may be adopted in which the contact 61 is provided between the electrode 1012 and the electrode 108 by forming the first conductor like the electrode 1012. Specifically, the electrode 108 is formed between the gate electrode 105 and the contact 61 which is the first contact, and the electrode 1012 may be formed such that the contact 61 is surrounded by the electrode 108 and the electrode 1012 insulated from the electrode 108.

Such a configuration can reduce a size increase in the Y-direction as compared with the case in which the contact 61 is surrounded by the electrode 101.

Note that the electrode 107 may be formed into a shape similar to the shape of the electrode 1012. Such a configuration can reduce a size increase in the Y-direction as compared with the case in which the contact 62 is surrounded by the electrode 107.

### 4 Fourth Embodiment

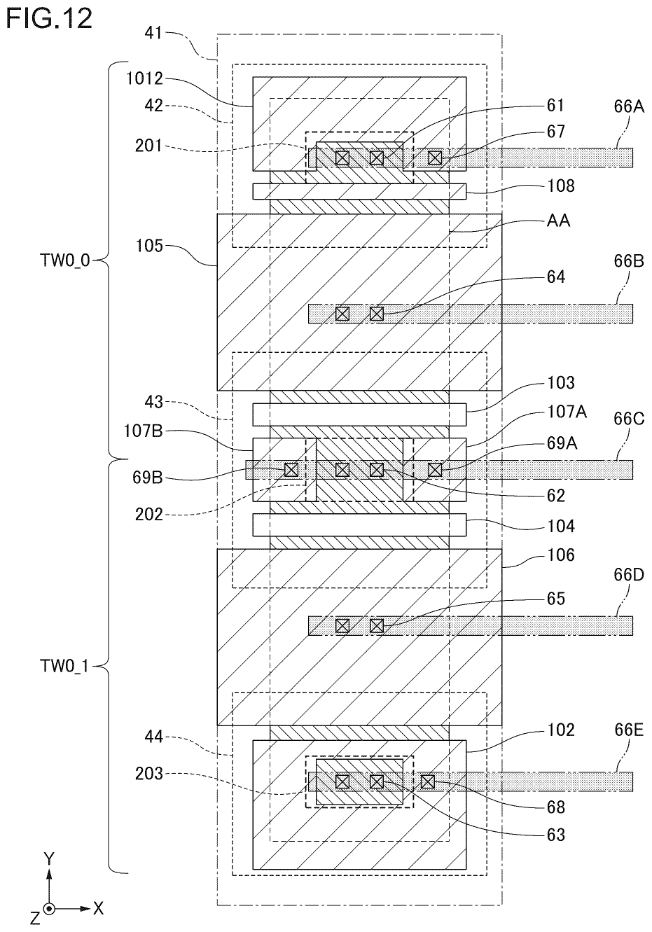

FIG. 12 shows the transfer transistor TW0_0 and the transfer transistor TW1_1 according to the present embodiment. The transfer transistors of the present embodiment are different from the transfer transistors according to the first embodiment in that the electrode 107 includes two electrodes 107A (an example of the “first conductor”) and 107B (an example of a “fifth conductor”), in that the electrode 108 (an example of the “fourth conductor”) is provided, and in that the electrode 1012 (an example of the “first conductor”) equivalent to the electrode 101 has a different shape.

The electrode 107 includes the two electrodes 107A and 107B. Both the electrodes are each provided at a position spaced from the contact 62 which is the second contact in the X-direction perpendicular to the channel direction of the transfer transistor TW0_0 and are provided so as to sandwich the contact 62. In other words, the contact 62 is formed between the electrode 107A and the electrode 107B. At this time, a portion of the electrode 103 which is the second conductor is formed between the electrode 105 which is the gate electrode and the electrode 107A, and another portion of the electrode 103 is formed between the electrode 105 and the electrode 107B.

The electrode 107A constituting the electrode 107 is connected to a contact 69A, and the electrode 107B is connected to a contact 69B. The contacts 69A and 69B are electrically connected to the contact 62 with the conductor layer 66C interposed therebetween. The electrodes 107A and 107B are thereby electrically connected to the contact 62 so as to have a potential substantially equal to the potential of the contact 62.

Also with such a configuration, both the ends of the electrode 103 in the Y-direction are insulated from the other adjacent electrodes. This can mitigate the concentration of equipotential lines to therefore raise the withstand voltage based on the potential difference between the second end and the gate electrode 105.

In addition, the electrode 107A and the electrode 107B are each opposed to the N− impurity diffusion region 43 with the insulation film 51 interposed therebetween.

Thus, when the transfer transistor TW0_0 according to the present embodiment is turned on, the voltage is also supplied to the electrode 107. This can cause an electric field to act from the electrode 107A and the electrode 107B on the N− impurity diffusion region 43 opposed in the Z-direction with the insulation film 51 interposed therebetween. Thus, the on-resistance of the transfer transistor TW0_0 can be lowered. The effects related to the configuration of the electrode 108 and the electrode 1012 have been stated in the third embodiment and the like, and description thereof will thus be omitted.

### 5 Fifth Embodiment

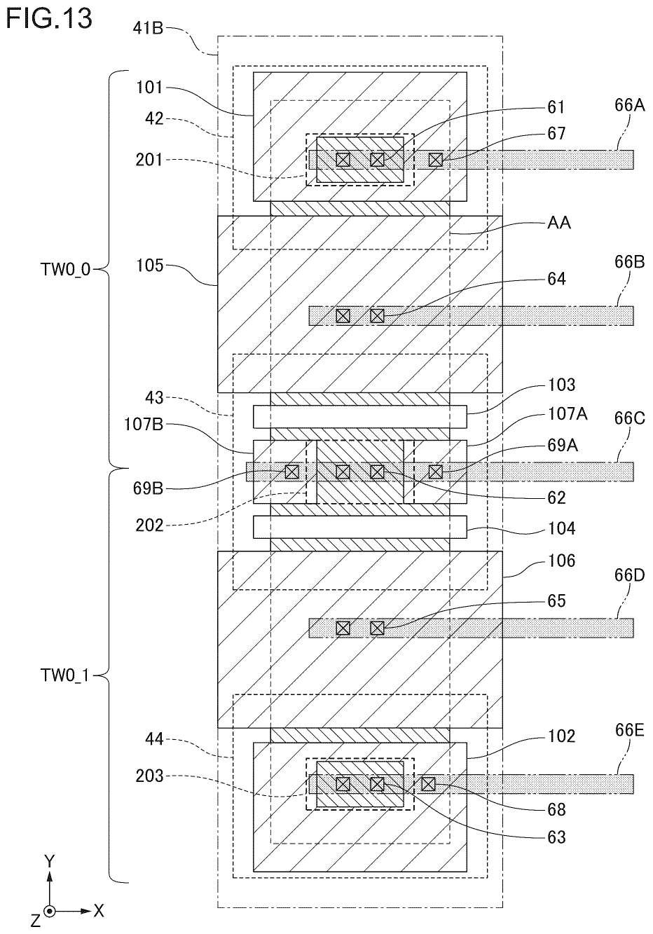

FIG. 13 shows the transfer transistor TW0_0 and the transfer transistor TW1_1 according to the present embodiment. The transfer transistors of the present embodiment are different from the transfer transistors according to the first embodiment in that the electrode 107 includes the two electrodes 107A (an example of the “first conductor”) and 107B (an example of the “fifth conductor”).

Also with such a configuration, both the ends of the electrode 103 in the Y-direction are insulated from the other adjacent electrodes. This can mitigate the concentration of equipotential lines to therefore raise the withstand voltage based on the potential difference between the second end and the gate electrode 105.

When the transfer transistor TW0_0 is turned on, the voltage is also supplied to the electrode 107. This can cause an electric field to act from the electrode 107A and the electrode 107B on the N− impurity diffusion region 43 opposed in the Z-direction with the insulation film 51 interposed therebetween to lower the on-resistance.

### 6 Sixth Embodiment

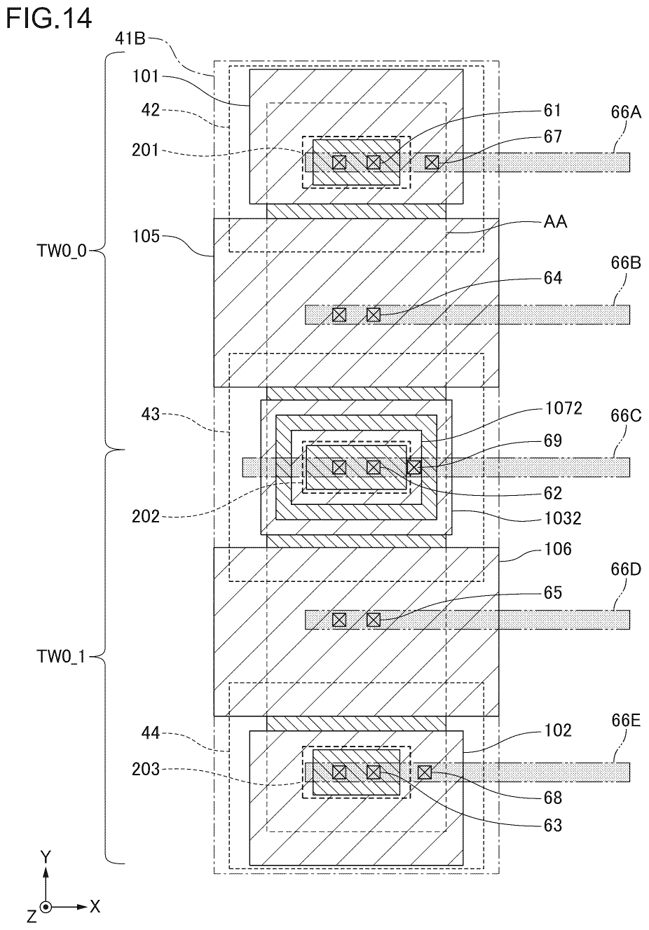

FIG. 14 shows the transfer transistor TW0_0 and the transfer transistor TW1_1 according to the present embodiment. The transfer transistors of the present embodiment are different from the transfer transistors according to the first embodiment in that the electrode 1032 (an example of the “second conductor”) equivalent to the electrode 103 is formed into a ring shape and in that an electrode 1072 (an example of the “third conductor”) equivalent to the electrode 107 has a different shape from the electrode 107.

In the present embodiment, the electrode 1072 is formed so as to surround the contact 62, and the electrode 1032 is formed so as to further surround the electrode 1072.

Also with such a configuration, the outer circumference in the Y-direction of the electrode 1032 and the inner circumference in the Y-direction opposed to the electrode 1072 are each insulated from the other adjacent electrodes. This can mitigate the concentration of equipotential lines to therefore raise the withstand voltage.

Note that a configuration may be adopted in which a sidewall is formed on each of the electrode 1072 and the electrode 1032, the sidewall of the electrode 1072 and the sidewall of the electrode 1032 being partially in contact with each other in a slit formed between the electrode 1072 and the electrode 1032 to plug the slit at least partially.

Such a configuration enables the most part of the region in the slit to be plugged up and the region in the opening of the electrode 101 and the like to be exposed. Thus, the conductor layer 221 or the like containing silicide can be selectively provided in the region in the opening through use of the self-alignment process.

The respective embodiments have been described above with reference to the specific examples. The transistors according to the respective embodiments can reduce voltage variation in the source region or the drain region, which results from an overlying conductor layer. In addition, the withstand voltage can be raised.

### 7 Seventh Embodiment

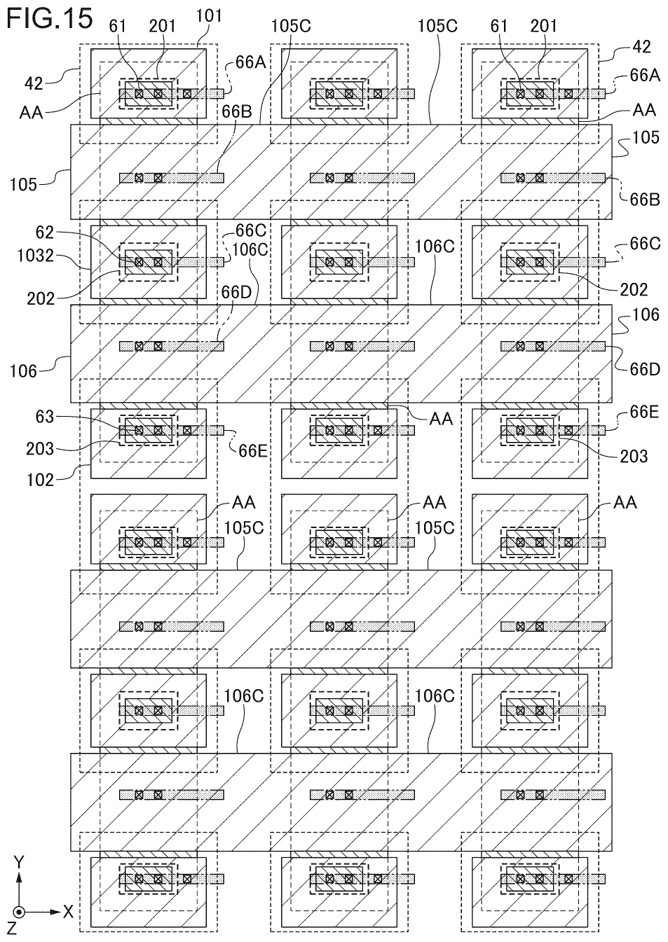

FIG. 15 shows an example in which twelve transfer transistors are arranged in order to show a modification of the gate electrode 105 and the gate electrode 106 according to the first embodiment. The respective transfer transistors in the present embodiment include components similar to the components of the transfer transistor according to the second embodiment (FIG. 10), but this is not a limitation, and the present embodiment may be applied to the transfer transistors according to the other embodiments. Note that in the present embodiment, common or alike components among the plurality of transfer transistors are denoted by the same or alike reference characters, and description thereof will be simplified or omitted as appropriate.

FIG. 15 shows a total of six active regions AA, three in the X-direction and two in the Y-direction, included in the semiconductor storage device 1. In each of the active region AA, the electrode 201 to be the source region or the drain region (an example of the “first region”), the electrode 202 to be the drain region or the source region (an example of the “second region”), the electrode 203 to be the drain region or the source region (an example of the “first region”), the contact 61 connected to the electrode 201, the contact 63 connected to the electrode 203, the contact 62 connected to the electrode 202, the gate electrode 105 and the gate electrode 106, the electrode 101 and the electrode 102, and the electrode 1032 are provided.

The semiconductor storage device 1 further includes an element isolation region having an insulator such as STI for electrically separating the respective active region AA from one another.

In the present embodiment, the semiconductor storage device 1 also includes two connection conductors 105C that connect the respective gate electrodes 105 of the three active regions AA adjacent to one another in the X-direction and two connection conductors 106C that connect the respective gate electrodes to each other.

The connection conductors 105C and the connection conductors 106C are each formed above the element isolation region.

With such a configuration, the connection conductor 105C and the connection conductor 106C are provided between the electrode 202 formed in one of the active regions AA, for example, and the conductor layer 66A and the conductor layer 66E provided in another one of the active regions AA adjacent in the X-direction. This can reduce variation in potential in the diffusion layer including the electrode 202 formed in the one of the active regions AA when a high voltage is supplied to a conductor layer such as the conductor layer 66A provided in the adjacent other one of the active regions AA, for example.

Note that the connection conductor 105C and the connection conductor 106C may have a length in the Y-direction less than the length of the electrode 105 (or the electrode 106) in the Y-direction.

A configuration may be adopted in which the connection conductors 105C and the connection conductors 106C are not provided so that the respective gate electrodes 105 of the three active regions AA adjacent to one another in the X-direction are not connected to one another.

### [Manufacturing Method]

Subsequently, a method for manufacturing the transfer transistors of the semiconductor storage device 1 according to the first embodiment will be described.

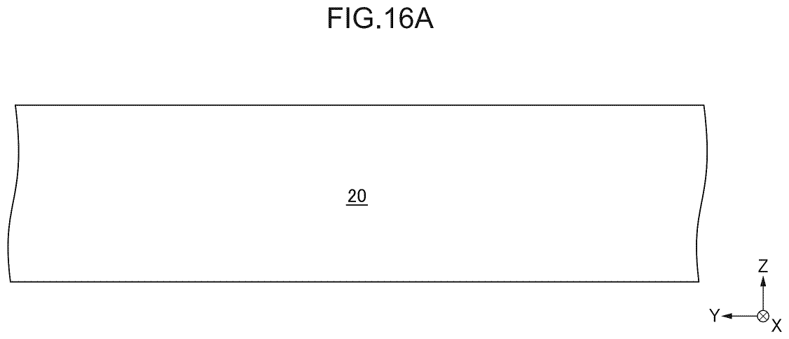

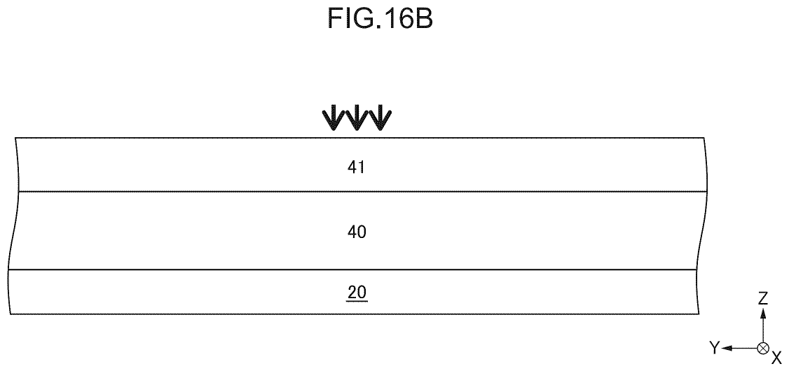

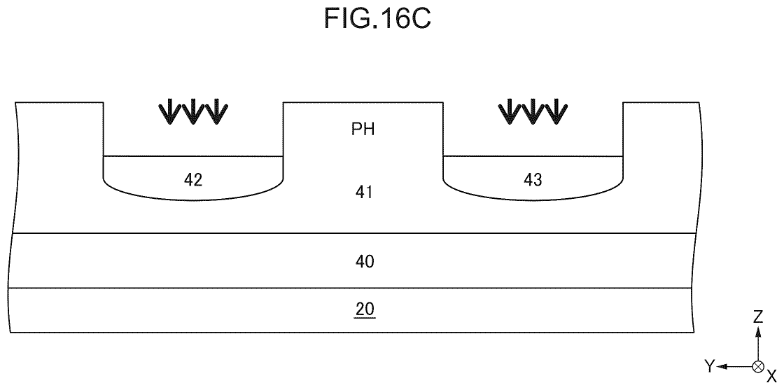

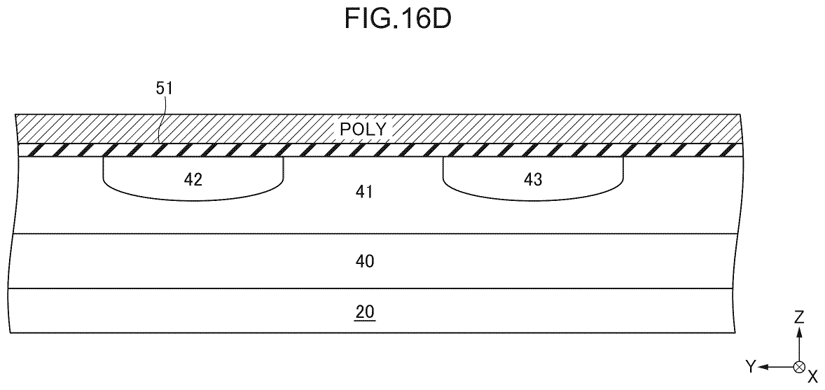

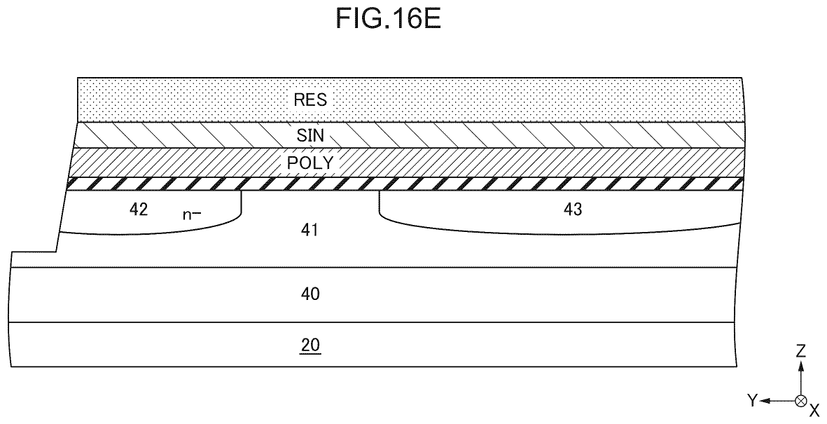

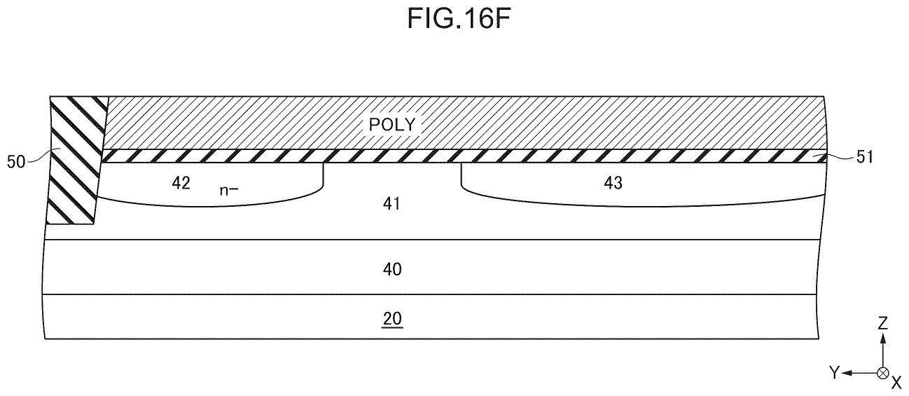

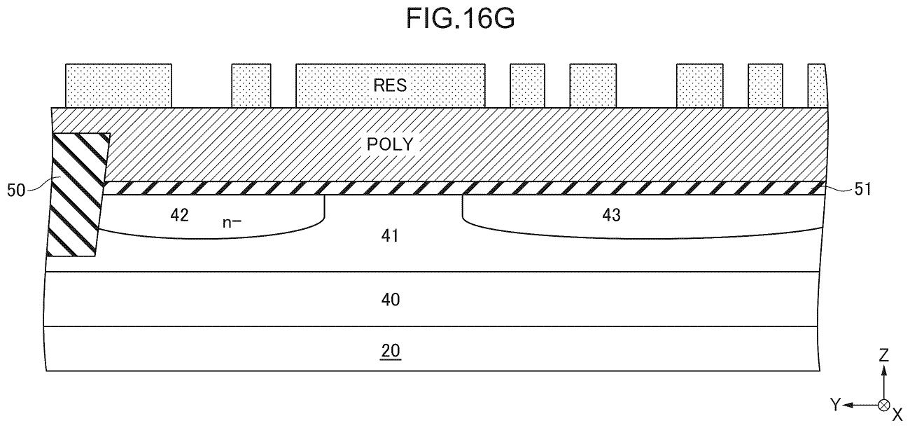

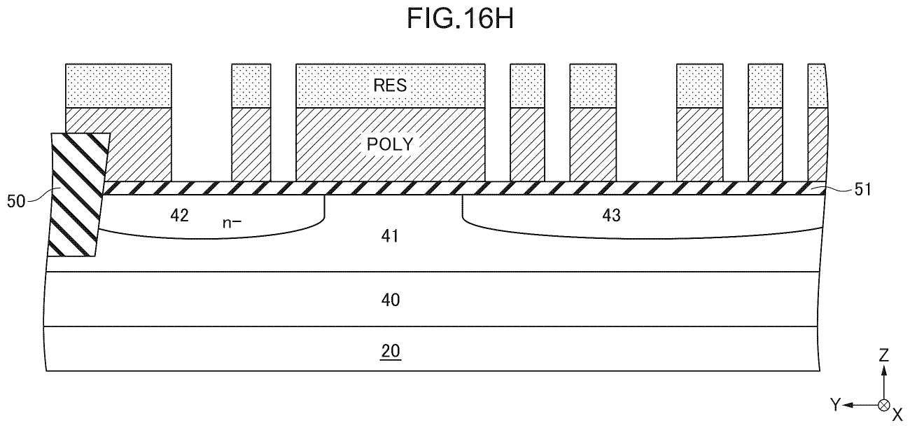

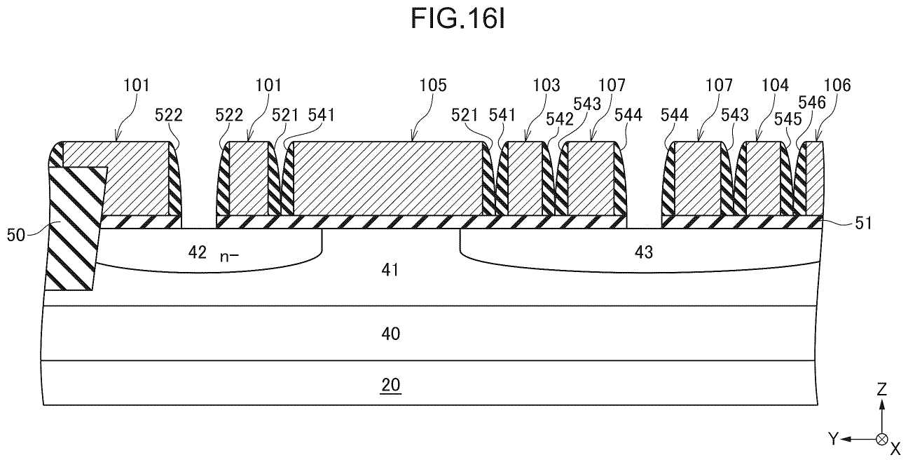

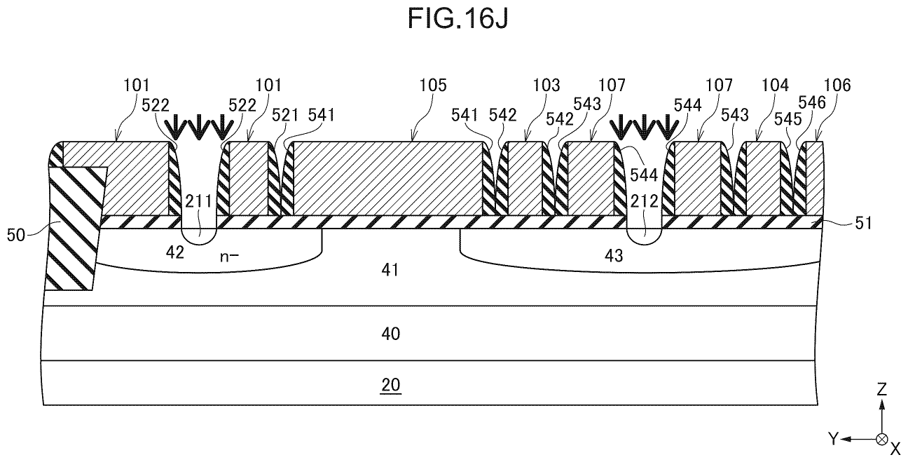

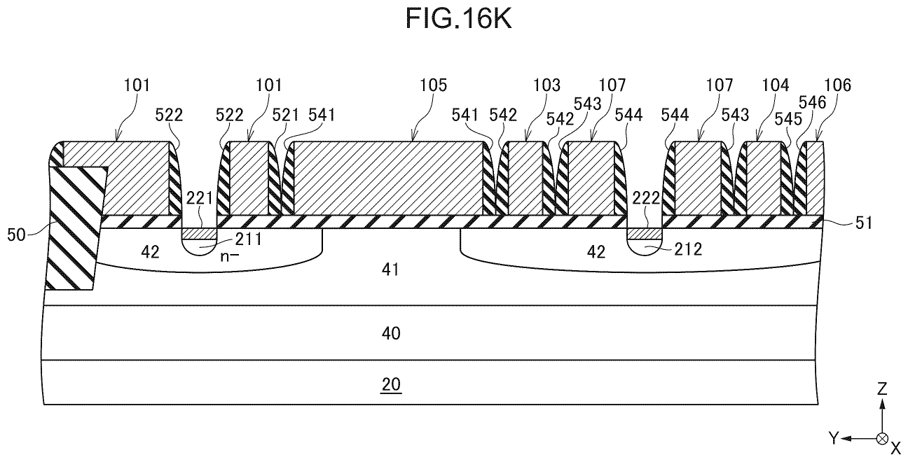

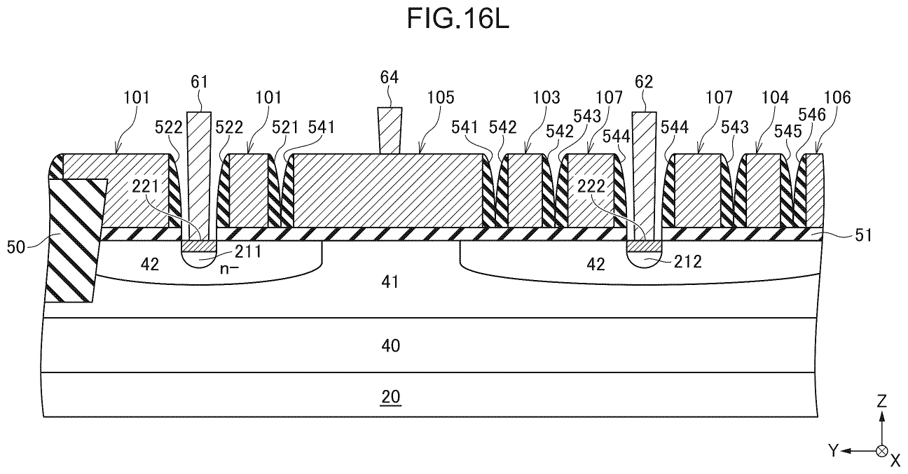

FIG. 16A to FIG. 16L are schematic views at the cross section taken along the line A-A in FIG. 7 for showing a process of manufacturing the transfer transistors.

FIG. 16A shows the P-type semiconductor substrate 20.

FIG. 16B shows a manner in which N-type and P-type impurities (dopants) are respectively injected into this semiconductor substrate 20, thereby forming an N-type well region 40 and further forming the P-type well region 41 on the N-type well region 40.

FIG. 16C shows a manner in which photoresist PH spread on the semiconductor substrate 20 having the N-type well region 40 and the P-type well region 41 formed on the N-type well region 40 is patterned and an N-type impurity is injected selectively, thereby forming the N− impurity diffusion region 42 and the N− impurity diffusion region 43 in selected regions.

FIG. 16D shows a manner in which after the photoresist PH is removed, the insulation film 51 is deposited above the surface of the semiconductor substrate 20, and a polysilicon film POLY is deposited on the insulation film 51.

FIG. 16E shows a manner in which after a nitride silicon film SIN as a mask is further deposited above the semiconductor substrate 20 on which the insulation film 51 has been deposited above the surface and the polysilicon film POLY has been deposited on the insulation film 51, a resist RES is spread, and then STI forming treatment is performed.

FIG. 16F shows a manner in which after an oxide insulation film, for example, is deposited to form the insulator layer 50, CMP polishing using the nitride silicon film SIN as a mask is performed, followed by etching back to remove the nitride silicon film SIN, and the polysilicon film POLY is further etched by RIE to bring an upper surface of the insulator layer 50 and an upper surface of the polysilicon film POLY to have a substantially equal height.

FIG. 16G shows a manner in which the polysilicon film POLY is deposited thereafter, the resist RES is spread, and then patterning for forming slits and openings is performed.

FIG. 16H shows a manner in which the polysilicon film POLY is etched by RIE to form a plurality of electrode components.

FIG. 16I shows a manner in which after the resist RES is removed, an oxide insulation film is deposited on side surfaces on the inner circumference and the outer circumference of the respective electrodes (such as the electrodes 101, 105, 103, 107, 104, and 106), thereby providing sidewalls (such as the sidewalls 522, 521, 541, 542, 544, 545, and 546) to bring the sidewalls of adjacent ones of the electrodes into contact with each other at the lower end.

FIG. 16J shows a manner in which an N+ impurity is injected into the openings of the electrode 101 and the electrode 107, thereby forming the N+ impurity diffusion regions 211 and 212 in a self-alignment manner.

FIG. 16K shows a manner in which after metal is deposited in the openings of the electrode 101 and the electrode 107 by CVD or the like, for example, thermal treatment is performed to form the conductor layer 221 and the conductor layer 222 containing silicide in a self-alignment manner. Note that as described above, silicide may be silicide (NiSi) containing nickel and silicon, silicide (NiPtSi) containing nickel, platinum, and silicon, silicide (CoSi) containing cobalt and silicon, or the like, for example. At this time, the conductor layer 221 and the conductor layer 222 containing silicide are formed selectively in the openings since the slits have been plugged up by the sidewalls.

FIG. 16L shows a manner in which after an interlayer insulation film not shown is deposited, the contact 61, the contact 62, and the contact 64 are formed.

Through the steps as described above, the transfer transistors shown in FIG. 7, FIG. 8A, and FIG. 8B can be manufactured.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device comprising:
a semiconductor substrate including a first region which is a source region or a drain region and a second region which is spaced from the first region in a first direction and which is the source region or the drain region;
a first contact connected to the first region;
a second contact connected to the second region;
a first memory cell connected to the first contact;
a gate electrode formed between the first contact and the second contact;
a first conductor including a portion having a height equal to a height of the gate electrode and electrically connected to the first contact; and
a second conductor including a portion having a height equal to the height of the gate electrode, having at least a portion formed between the gate electrode and the second contact, and insulated from the gate electrode, the first contact, and the second contact.

2. The semiconductor storage device according to claim 1, wherein the first conductor surrounds the first contact.

3. The semiconductor storage device according to claim 2, further comprising:
a first wiring layer connected to the first contact; and
a third contact that connects the first wiring layer and the first conductor.

4. The semiconductor storage device according to claim 2, wherein the semiconductor substrate includes a first high-resistance diffusion layer that surrounds the first region and has a resistance larger than a resistance of the first region, further comprising
an insulation film provided between the first conductor and the first high-resistance diffusion layer.

5. The semiconductor storage device according to claim 1, further comprising a third conductor that surrounds the second contact, wherein
the second conductor has at least a portion formed between the gate electrode and the third conductor.

6. The semiconductor storage device according to claim 5, further comprising a fourth contact connected to the third conductor for electrically connecting the second contact and the third conductor.

7. The semiconductor storage device according to claim 5, wherein the semiconductor substrate includes a second high-resistance diffusion layer that surrounds the second region and has a resistance larger than a resistance of the second region, further comprising
an insulation film provided between the third conductor and the second high-resistance diffusion layer.

8. The semiconductor storage device according to claim 5, further comprising:
a gate electrode sidewall formed on each of at least two lateral walls of the gate electrode;
a second sidewall formed on each of at least two lateral walls of the second conductor; and
a third sidewall formed on each of at least two lateral walls of the third conductor, wherein
a portion of the gate electrode sidewall and a first portion of the second sidewall are in contact with each other, and
a second portion of the second sidewall and a portion of the third sidewall are in contact with each other.

9. The semiconductor storage device according to claim 8, wherein
a first slit is formed between the gate electrode and the second conductor, and the portion of the gate electrode sidewall and the first portion of the second sidewall are in contact with each other in the first slit, and
a second slit is formed between the second conductor and the third conductor, and the second portion of the second sidewall and the portion of the third sidewall are in contact with each other in the second slit.

10. The semiconductor storage device according to claim 1, wherein the second conductor is floating.

11. The semiconductor storage device according to claim 1, further comprising a constant potential wiring layer for supplying a constant potential to the second conductor.

12. The semiconductor storage device according to claim 1, wherein the first memory cell constitutes a memory cell of a NAND flash memory, further comprising
a first wiring layer formed above the first conductor and configured to connect a word line of the first memory cell and the first contact.

13. The semiconductor storage device according to claim 1, wherein the second conductor surrounds the second contact.

14. The semiconductor storage device according to claim 1, further comprising a fourth conductor including a portion having a height equal to a height of the gate electrode, having at least a portion formed between the gate electrode and the first contact, and insulated from the gate electrode, the first contact, and the second contact.

15. The semiconductor storage device according to claim 14, wherein the first contact is formed between at least a portion of the first conductor and the fourth conductor.

16. The semiconductor storage device according to claim 1, further comprising a fifth conductor electrically connected to the second contact, wherein
the second conductor has at least a portion formed between the gate electrode and the fifth conductor.

17. The semiconductor storage device according to claim 16, further comprising a sixth conductor electrically connected to the second contact, wherein
the second contact is formed between the fifth conductor and the sixth conductor.

18. The semiconductor storage device according to claim 5, wherein the second conductor surrounds the third conductor.

19. The semiconductor storage device according to claim 1, further comprising:
a plurality of active regions each provided with the first region, the second region, the first contact, the second contact, the gate electrode, the first conductor, and the second conductor;
an element isolation region that electrically isolates one of the active regions and another one of the active regions; and
a connection conductor provided on the element isolation region that isolates the one of the active regions and the other one of the active regions adjacent in a second direction that intersects the first direction, the connection conductor connecting the gate electrode of the one of the active regions and the gate electrode of the other one of the active regions.
